(19) United States
(12) Patent Application Publication
(10) Pub. No.: US 2024/0030388 A1
(43) Pub. Date: Jan. 25, 2024

(54) DISPLAY DEVICE AND MANUFACTURING METHOD FOR THE SAME

(71) Applicant: Samsung Display Co., LTD., Yongin-si (KR)

(72) Inventors: Hoon KIM, Yongin-si (KR); Min Joo KIM, Yongin-si (KR); Je Won YOO, Yongin-si (KR); Seung Kyu LEE, Yongin-si (KR); Yong Sik HWANG, Yongin-si (KR)

(73) Assignee: Samsung Display Co., LTD., Yongin-si (KR)

(21) Appl. No.: 18/338,498

(22) Filed: Jun. 21, 2023

(30) Foreign Application Priority Data
Jul. 19, 2022 (KR) 10-2022-0089190

(51) Int. Cl. H01L 33/50; H01L 33/60; G09G 3/20

(52) U.S. Cl. CPC H01L 33/505; H01L 33/60; G09G 3/2003; G09G 2300/0413; G09G 2300/0452

(57) ABSTRACT

A display device includes a display area and a non-display area; and a pixel disposed on the display area of a substrate. The pixel includes a first sub-pixel disposed in a first sub-pixel area, the first sub-pixel emitting light of a first color; a second sub-pixel disposed in a second sub-pixel area, the second sub-pixel emitting light of a second color; and a third sub-pixel disposed in a third sub-pixel area, the third sub-pixel emitting light of a third color. Each of two sub-pixels among the first sub-pixel, the second sub-pixel, and the third sub-pixel includes a light emitting element emitting light of the third color, and the other sub-pixel among the first sub-pixel, the second sub-pixel, and the third sub-pixel includes a light emitting element emitting light of a color different from the third color.

### CROSS-REFERENCE TO RELATED APPLICATION

This application claims priority to and benefits of Korean patent application No. 10-2022-0089190 under 35 U.S.C. § 119, filed on Jul. 19, 2022 in the Korean Intellectual Property Office (KIPO), the entire disclosure of which is incorporated herein by reference.

### BACKGROUND

### 1. Technical Field

The disclosure generally relates to a display device and a manufacturing method for the same.

### 2. Description of the Related Art

Recently, as interest in information displays is increased, research and development of display devices have been continuously conducted.

### SUMMARY

Embodiments provide a display device and a manufacturing method for the same, in which light efficiency and luminance are improved.

Embodiments also provide a display device and a manufacturing method for the same, in which a manufacturing process is simplified.

The technical objectives to be achieved by the disclosure are not limited to those described herein, and other technical objectives that are not mentioned herein would be clearly understood by a person skilled in the art from the description of the disclosure.

In accordance with an aspect of the disclosure, there is provided a display device including a display area and a non-display area; and a pixel disposed on a substrate in the display area, wherein the pixel includes a first sub-pixel disposed in a first sub-pixel area, the first sub-pixel emitting light of a first color; a second sub-pixel disposed in a second sub-pixel area, the second sub-pixel emitting light of a second color; and a third sub-pixel disposed in a third sub-pixel area, the third sub-pixel emitting light of a third color, and wherein each of two sub-pixels among the first sub-pixel, the second sub-pixel, and the third sub-pixel includes a light emitting element emitting light of the third color, and the other sub-pixel among the first sub-pixel, the second sub-pixel, and the third sub-pixel includes a light emitting element emitting light of a color different from the third color.

Each of the first sub-pixel and the third sub-pixel may include a first light emitting element emitting light of the third color, and the second sub-pixel may include a second light emitting element emitting light of the second color.

The first sub-pixel may include a first color conversion layer including at least one first color conversion particle, and each of the second sub-pixel and the third sub-pixel may include a light scattering layer including at least one light scattering particle.

The first sub-pixel may include a pixel circuit layer disposed on the substrate, the pixel circuit layer including a transistor; a display element layer disposed on the pixel circuit layer, the display element layer including the first light emitting element disposed in a first emission area; a first color conversion layer disposed on the display element layer to overlap the first emission area in a plan view, the first color conversion layer including at least one first color conversion particle; and a color filter layer disposed on the first color conversion layer.

The display element layer may further include a bank provided in a first non-emission area, the bank including an opening corresponding to the first emission area.

The first sub-pixel may further include a dummy bank disposed on the bank, corresponding to the first non-emission area.

The first sub-pixel may further include a capping layer disposed between the first color conversion layer and the color filter.

The capping layer may be disposed directly on the first color conversion layer and the dummy bank.

The second sub-pixel may include a pixel circuit layer disposed on the substrate, the pixel circuit layer including a transistor; a display element layer disposed on the pixel circuit layer, the display element layer including the second light emitting element disposed in a second emission area; and a first light scattering layer disposed on the display element layer to overlap the second emission area in a plan view, the first light scattering layer including at least one first light scattering particle.

The display element layer may further include a bank provided in a second non-emission area, the bank including an opening corresponding to the second emission area.

The second sub-pixel may further include a dummy bank disposed on the bank, corresponding to the second non-emission area.

The second sub-pixel may further include a capping layer disposed on the dummy bank and the first light scattering layer.

The third sub-pixel may include a pixel circuit layer disposed on the substrate, the pixel circuit layer including a transistor; a display element layer disposed on the pixel circuit layer, the display element layer including the first light emitting element disposed in a third emission area; and a second light scattering layer disposed on the display element layer to overlap the third emission area in a plan view, the second light scattering layer including at least one second light scattering particle.

Each of the second sub-pixel and the third sub-pixel may include a first light emitting element emitting light of the third color, and the first sub-pixel may include a third light emitting element emitting light of the first color.

The second sub-pixel may include a second color conversion layer including at least one second color conversion particle, and each of the first sub-pixel and the third sub-pixel may include a light scattering layer including at least one light scattering particle.

Light of the first color may be red light, light of the second color may be green light, and light of the third color may be blue light.

In accordance with another aspect of the disclosure, there is provided a manufacturing method for a display device, the method including forming a display element layer including light emitting elements and a bank; forming a light scattering layer in each of a second sub-pixel area and a third sub-pixel area; forming a dummy bank on the bank; forming a color conversion layer in a first sub-pixel area; and forming a color filter layer on the color conversion layer of the first sub-pixel area, wherein the display device includes a first sub-pixel which is disposed on the first sub-pixel area and emits light of a first color, a second sub-pixel which is disposed on the second sub-pixel area and emits light of a second color, and a third sub-pixel which is disposed on the third sub-pixel area and emits light of a third color.

The forming of the display element layer may include providing a first light emitting element emitting light of the third color in each of the first sub-pixel area and the third sub-pixel area, and providing a second light emitting element emitting light of the second color in the second sub-pixel area.

The light of the first color may be red light, the light of the second color may be green light, and the light of the third color may be blue light.

The light of the first color may be green light, the light of the second color may be red light, and the light of the third color may be blue light.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be more thorough and complete, and will convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a perspective view schematically illustrating a light emitting element in accordance with embodiments of the disclosure.

FIG. 2 is a sectional view illustrating an embodiment of the light emitting element shown in FIG. 1.

FIG. 3 is a schematic plan view illustrating a display device in accordance with embodiments of the disclosure.

FIG. 4A is a schematic diagram of an equivalent circuit illustrating an example of a pixel (sub-pixel) included in the display device shown in FIG. 3.

FIG. 4B is a schematic diagram of an equivalent circuit illustrating another example of the pixel (sub-pixel) included in the display device shown in FIG. 3.

FIG. 5 is a schematic plan view illustrating an example of the pixel included in the display device shown in FIG. 3.

FIG. 6 is a schematic plan view illustrating an example of a first sub-pixel included in the pixel shown in FIG. 5.

FIG. 7 is a schematic plan view illustrating an example of a second sub-pixel included in the pixel shown in FIG. 5.

FIG. 8 is a schematic plan view illustrating an example of a third sub-pixel included in the pixel shown in FIG. 5.

FIG. 9 is a schematic sectional view illustrating an example taken along line I-I′ shown in FIG. 6.

FIG. 10 is a schematic sectional view illustrating an example of a pixel circuit layer of the first sub-pixel shown in FIG. 6.

FIG. 11 is a schematic sectional view illustrating an example taken along line II-II′ shown in FIG. 7.

FIG. 12 is a schematic sectional view illustrating an example taken along line III-III′ shown in FIG. 5.

FIG. 13 is a schematic plan view illustrating an example of the pixel included in the display device shown in FIG. 3.

FIG. 14 is a schematic sectional view illustrating an example taken along line IV-IV′ shown in FIG. 13.

FIGS. 15 to 21 are schematic sectional views illustrating a manufacturing method for the display device in accordance with embodiments of the disclosure.

### DETAILED DESCRIPTION OF THE EMBODIMENTS

Like numbers refer to like elements throughout. In the drawings, the thickness of certain lines, layers, components, elements or features may be exaggerated for clarity. It will be understood that, although the terms “first”, “second”, and the like may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise. In the following description, singular forms in the disclosure are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in more detail with reference to the accompanying drawings. Throughout the drawings, the same reference numerals are given to the same elements, and their repetitive descriptions will be omitted.

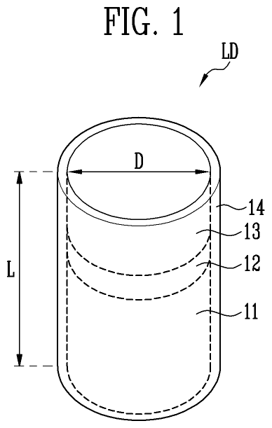

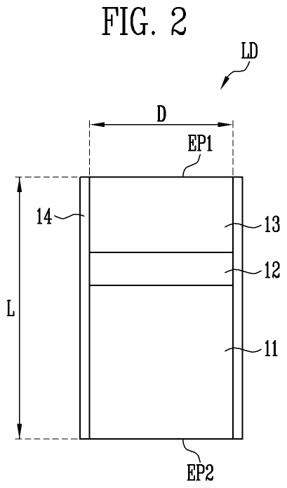

FIG. 1 is a perspective view schematically illustrating a light emitting element in accordance with embodiments of the disclosure. FIG. 2 is a sectional view illustrating an embodiment of the light emitting element shown in FIG. 1.

Referring to FIGS. 1 and 2, a light emitting element LD may include a first semiconductor layer 11, a second semiconductor layer 13, and an active layer 12 interposed between the first and second semiconductor layers 11 and 13. In an example, the light emitting element LD may be implemented as a light emitting stack structure (or stack pattern) in which the first semiconductor layer 11, the active layer 12, and the second semiconductor layer 13 are sequentially stacked each other.

The light emitting element LD may be provided in a shape extending in a direction.

When assuming that an extending direction of the light emitting element LD is a length direction, the light emitting element LD may include a first end portion EP1 and a second end portion EP2 in the length direction. One of the first semiconductor layer 11 and the second semiconductor layer 13 may be located at the first end portion EP1 of the light emitting element LD, and the other of the first semiconductor layer 11 and the second semiconductor layer 13 may be located at the second end portion EP2 of the light emitting element LD.

The light emitting element LD may be provided in various shapes. In an example, the light emitting element LD may have a rod-like shape, a bar-like shape, a pillar-like shape, or the like, which is long in its length direction (e.g., its aspect ratio is greater than about 1) as shown in FIG. 1. In another example, the light emitting element LD may have a rod-like shape, a bar-like shape, a pillar-like shape, or the like, which is short in its length direction (e.g., its aspect ratio is smaller than about 1). In still another example, the light emitting element LD may have a rod-like shape, a bar-like shape, a pillar-like shape, or the like, of which aspect ratio is about 1.

In an example, the light emitting element LD may include a light-emitting diode (LED) manufactured small enough to have a diameter D and/or a length L to a degree of nano scale (or nanometers) to micro scale (micrometers).

In case that the light emitting element LD is long in its length direction (e.g., its aspect ratio is greater than about 1), the diameter D of the light emitting element LD may be about 0.5 μm to about 6 μm, and the length L of the light emitting element LD may be about 1 μm to about 10 μm. However, the diameter D and the length L of the light emitting element LD are not limited thereto, and the size of the light emitting element LD may be changed to accord with requirement conditions (or design conditions) of a lighting device or a self-luminous display device, to which the light emitting element LD is applied.

The first semiconductor layer 11 may include, for example, at least one n-type semiconductor layer. The first semiconductor layer 11 may include an upper surface contacting the active layer 12 and a lower surface exposed to the outside in the length direction of the light emitting element LD. The lower surface of the first semiconductor layer 11 may be an end portion (or bottom end portion) of the light emitting element LD.

The active layer 12 is formed on the first semiconductor layer 11, and may be formed in a single or multiple quantum well structure. In an example, in case that the active layer 12 is formed in the multiple quantum well structure, a barrier layer, a strain reinforcing layer, and a well layer, which constitute a part, may be periodically and repeatedly stacked each other in the active layer 12. The strain reinforcing layer may have a lattice constant smaller than that of the barrier layer, to further reinforce strain, e.g., compressive strain applied to the well layer. However, this is merely illustrative, and the structure of the active layer 12 is not limited to the above-described embodiment.

The active layer 12 may emit light having a wavelength of about 400 nm to about 900 nm, and use a double heterostructure. The active layer 12 may include a first surface contacting the first semiconductor layer 11 and a second surface contacting the second semiconductor layer 13.

In an embodiment, a color (or light output color) of the light emitting element LD may be determined according to a wavelength of light emitted from the active layer 12. The color of the light emitting element LD may determine a color of a pixel corresponding thereto. For example, the light emitting element LD may emit red light, green light, or blue light.

In case that an electric field having a voltage or more (e.g., a predetermined or selectable voltage or more) is applied to the end portions of the light emitting element LD, the light emitting element LD emits light as electron-hole pairs are combined in the active layer 12. The light emission of the light emitting element LD is controlled by using such a principle, so that the light emitting element LD can be used as a light source (or light emitting source) for various light emitting devices, including a pixel of a display device.

The second semiconductor layer 13 is formed on the second surface of the active layer 12, and may include a semiconductor layer having a type different from that of the first semiconductor layer 11.

The second semiconductor layer 13 may include a lower surface contacting the second surface and an upper surface exposed to the outside in the length direction of the light emitting element LD. The upper surface of the second semiconductor layer 13 may be another end portion (or top end portion) of the light emitting element LD.

In an embodiment, the first semiconductor layer 11 and the second semiconductor layer 13 may have different thicknesses in the length direction of the light emitting element LD. In an example, the first semiconductor layer 11 may have a thickness relatively greater than that of the second semiconductor layer 13 in the length direction of the light emitting element LD. Accordingly, the active layer 12 of the light emitting element LD may be located more adjacent to the upper surface of the second semiconductor layer 13 than the lower surface of the first semiconductor layer 11.

Although FIGS. 1 and 2 illustrate that each of the first semiconductor layer 11 and the second semiconductor layer 13 is configured with (or formed as) a layer, the embodiment of the disclosure is not limited thereto. In an embodiment, each of the first semiconductor layer 11 and the second semiconductor layer 13 may further include at least one layer, e.g., a clad layer and/or a Tensile Strain Barrier Reducing (TSBR) layer according to the material of the active layer 12. The TSBR layer may be a strain reducing layer disposed between semiconductor layers having different lattice structures to perform a buffering function for reducing a lattice constant difference. The TSBR may be configured with (or formed as) a p-type semiconductor layer such as p-GAInP, p-AlInP or p-AlGaInP, but the disclosure is not limited thereto.

In an embodiment, the light emitting element LD may further include a contact electrode (hereinafter referred to as a “first contact electrode”) disposed on the top of the second semiconductor layer 13, in addition to the first semiconductor layer 11, the active layer 12, and the second semiconductor layer 13, which are described above. In other embodiments, the light emitting element LD may further include another contact electrode (hereinafter referred to as a “second contact electrode”) disposed at an end of the first semiconductor layer 11.

Each of the first and second contact electrodes may be an ohmic contact electrode, but the disclosure is not limited thereto. In embodiments, each of the first and second contact electrodes may be a Schottky contact electrode. The first and second contact electrodes may include a conductive material.

In embodiments, the light emitting element LD may further include an insulative film 14 (or insulating film). However, in an embodiment, the insulative film 14 may be omitted, and be provided to cover only portions of the first semiconductor layer 11, the active layer 12, and the second semiconductor layer 13.

The insulative film 14 can prevent an electrical short circuit which may occur in case that the active layer 12 contacts a conductive material in addition to the first semiconductor layer 11 and the second semiconductor layer 13. Also, the insulative film 14 minimizes a surface defect of the light emitting element LD, thereby improving the lifespan and light emission efficiency of the light emitting element LD. Whether the insulative film is provided is not limited as long as the active layer 12 can prevent occurrence of a short circuit with external conductive material.

The insulative film 14 may be provided in a shape entirely surrounding an outer circumference of the light emitting stack structure including the first semiconductor layer 11, the active layer 12, and the second semiconductor layer 13.

Although a case where the insulative film 14 is provided in a shape entirely surrounding an outer circumference of each of the first semiconductor layer 11, the active layer 12, and the second semiconductor layer 13 is described in the above-described embodiment, the disclosure is not limited thereto.

The insulative film 14 may include a transparent insulating material. For example, the insulative film 14 may include at least one insulating material selected from the group consisting of silicon oxide (SiOₓ), silicon nitride (SiNₓ), silicon oxynitride (SiOₓN_{y}), aluminum oxide (AlOₓ), titanium dioxide (TiO₂), hafnium oxide (HfOₓ), titanium strontium oxide (SrTiOₓ), cobalt oxide (CoₓO_{y}), magnesium oxide (MgO), zinc oxide (ZnO), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InₓO_{y}:H, niobium oxide (NbₓO_{y}), magnesium fluoride (MgFₓ), aluminum fluoride (AlFₓ), Alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), vanadium nitride (VN), and the like. However, the disclosure is not limited thereto, and various materials having insulating properties may be used as the material of the insulative film 14.

The insulative film 14 may be provided in the form of a single layer or be provided in the form of a multi-layer including at least two layers.

The above-described light emitting element LD may be used as a light emitting source (or light source) for various display devices. The light emitting element LD may be manufactured through a surface treatment process. For example, in case that light emitting elements LD are mixed in a liquid solution (or solvent) to be supplied to each pixel area (e.g., an emission area of each pixel or an emission area of each sub-pixel), each light emitting element LD may be surface-treated such that the light emitting elements LD are not unequally condensed in the solution but equally dispersed in the solution.

A light emitting part (or light emitting device) including the above-described light emitting element LD may be used in various types of devices that require a light source, including a display device. In case that light emitting elements LD are disposed in an emission area of each pixel of a display panel, the light emitting elements LD may be used as a light source of the pixel. However, the application field of the light emitting element LD is not limited to the above-described example. For example, the light emitting element LD may be used for other types of electronic devices that require a light source, such as a lighting device.

However, this is merely illustrative, and a light emitting element applied to display devices in accordance with embodiments of the disclosure is not limited thereto. For example, the light emitting element may be a flip-chip-type micro light emitting diode or an organic light emitting element including an organic emitting layer.

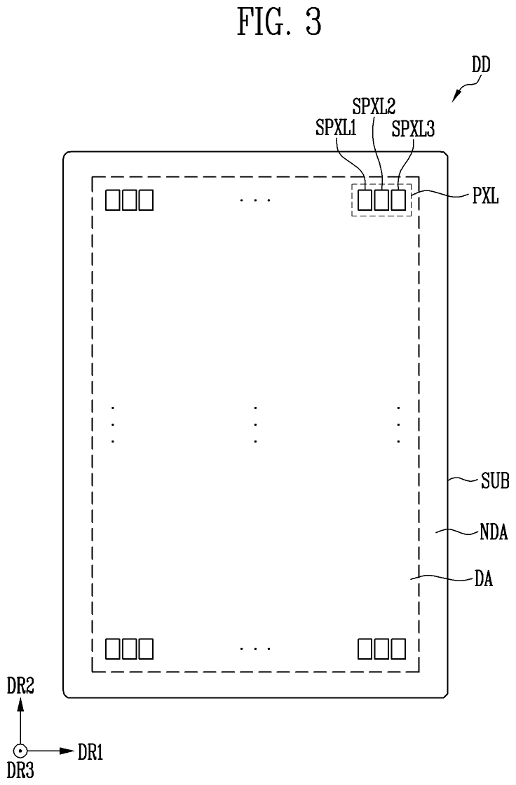

FIG. 3 is a schematic plan view illustrating a display device in accordance with embodiments of the disclosure. FIG. 3 illustrates a display device DD as an example of an electronic device which can use, as a light source, the light emitting element LD described in FIGS. 1 and 2.

For convenience of description, FIG. 3 illustrates a structure of the display device DD based on a display area DA. However, In an embodiment, at least one driving circuit (e.g., at least one of a scan driver and a data driver), lines, and/or pads, which are not shown, may be further included (or disposed) in the display device DD.

Embodiments of the disclosure may be applied to the display device DD as long as the display device DD is an electronic device in which a display surface is applied to at least one surface thereof, such as a smartphone, a television, a tablet personal computer (PC), a mobile phone, a video phone, an electronic-book reader, a desktop PC, a laptop PC, a netbook computer, a workstation, a server, a personal digital assistant (PDA), a portable multimedia player (PMP), an MP3 player, a medical device, a camera, or a wearable device.

Referring to FIG. 3, the display device DD may include a substrate SUB and pixels PXL provided on the substrate SUB.

The substrate SUB is used to form a base member of a display panel of the display device DD, and may be a rigid or flexible substrate or film. In an example, the substrate SUB may be configured as a rigid substrate made of glass or tempered glass, a flexible substrate (or thin film) made of plastic or metal, or at least one insulating layer. However, this is merely illustrative, and the material and/or property of the substrate SUB is not particularly limited.

In an embodiment, the substrate SUB may be substantially transparent. The term “substantially transparent” may mean that light can be transmitted with a transmittance or more (e.g., a predetermined or selectable transmittance or more). In another embodiment, the substrate SUB may be translucent or opaque. Also, in embodiments, the substrate SUB may include a reflective material.

The substrate SUB may include the display area DA for displaying an image and a non-display area NDA excluding the display area DA.

The pixels PXL may be provided in the display area DA. Various lines, pads, and/or a built-in circuit, which are electrically connected to the pixels PXL of the display area DA, may be provided in the non-display are NDA.

The non-display area NDA may be located adjacent to the display area DA. The non-display area NDA may be provided at at least one side of the display area DA. For example, the non-display area NDA may surround a circumference (or edge) of the display area DA.

The pixel PXL may include sub-pixels SPXL1 to SPXL3. For example, the pixel PXL may include a first sub-pixel SPXL1, a second sub-pixel SPXL2, and a third sub-pixel SPXL3.

Each of the sub-pixels SPXL1 to SPXL3 may emit light of a color (e.g., a predetermined or selectable color). In embodiments, the sub-pixels SPXL1 to SPXL3 may emit rays of light of different colors. For example, the first sub-pixel SPXL1 may emit light of a first color, the second sub-pixel SPXL2 may emit light of a second color, and the third sub-pixel SPXL3 may emit light of a third color. For example, the first sub-pixel SPXL1 may be a red pixel emitting light of red, the second sub-pixel SPXL2 may be a green pixel emitting light of green, and the third sub-pixel SPXL3 may be a blue pixel emitting light of blue. However, the disclosure is not limited thereto.

Each of the sub-pixels SPXL1 to SPXL3 may have a light emitting element as a light source. For example, each of the sub-pixels SPXL1 to SPXL3 may include the light emitting element LD described with reference to FIGS. 1 and 2.

In an embodiment, at least some of the sub-pixels SPXL1 to SPXL3 may include a light emitting element emitting light of a same color.

For example, the first sub-pixel SPXL1 and the third sub-pixel SPXL3 among the sub-pixels SPXL1 to SPXL3 may include a light emitting element emitting light of a same color, and the second sub-pixel SPXL2 may include a light emitting element emitting light of a color different from the color of light emitted from the light emitting element included in the first sub-pixel SPXL1 and the third sub-pixel SPXL3. In an example, the first sub-pixel SPXL1 emitting light of the first color (e.g., light of red) and the third sub-pixel SPXL3 emitting light of the third color (e.g., light of blue) may include a light emitting element (e.g., a first light emitting element) emitting light of the third color (e.g., light of blue). The first sub-pixel SPXL1 may include a color conversion layer and/or a color filter, disposed above the light emitting element (e.g., the first light emitting element), to emit light of the first color (e.g., light of red). The second sub-pixel SPXL2 may include a light emitting element (e.g., a second light emitting element) emitting light of the second color (e.g., light of green). In embodiments, each of the second sub-pixel SPXL2 and the third sub-pixel SPXL3 may include a light scattering layer disposed above the light emitting element, and emit light of a color (e.g., the second color (e.g., green) or the third color (e.g., blue)) corresponding to a color of light emitted therefrom.

In another example, the second sub-pixel SPXL2 and the third sub-pixel SPXL3 among the sub-pixels SPXL1 to SPXL3 may include a light emitting element emitting light of a same color, and the first sub-pixel SPXL1 may include a light emitting element emitting light of a color different from the color of light emitted from the light emitting element included in the second sub-pixel SPXL2 and the third sub-pixel SPXL3. In an example, the second sub-pixel SPXL2 emitting light of the second color (e.g., light of green) and the third sub-pixel SPXL3 emitting light of the third color (e.g., light of blue) may include a light emitting element (e.g., a first light emitting element) emitting light of the third color (e.g., light of blue). The second sub-pixel SPXL2 may include a color conversion layer and/or a color filter, disposed above the light emitting element (e.g., the first light emitting element), to emit light of the second color (e.g., light of green). The first sub-pixel SPXL1 may include a light emitting element (e.g., a third light emitting element) emitting light of the first color (e.g., light of red). In embodiments, each of the first sub-pixel SPXL1 and the third sub-pixel SPXL3 may include a light scattering layer disposed above the light emitting element, and emit light of a color (e.g., the first color (e.g., red) or the third color (e.g., blue)) corresponding to a color of light emitted therefrom.

However, this is merely illustrative, and the color, kind, and/or number of sub-pixels SPXL1 to SPXL3 constituting each pixel PXL are not particularly limited. For example, the color of light emitted by each pixel PXL may be variously changed.

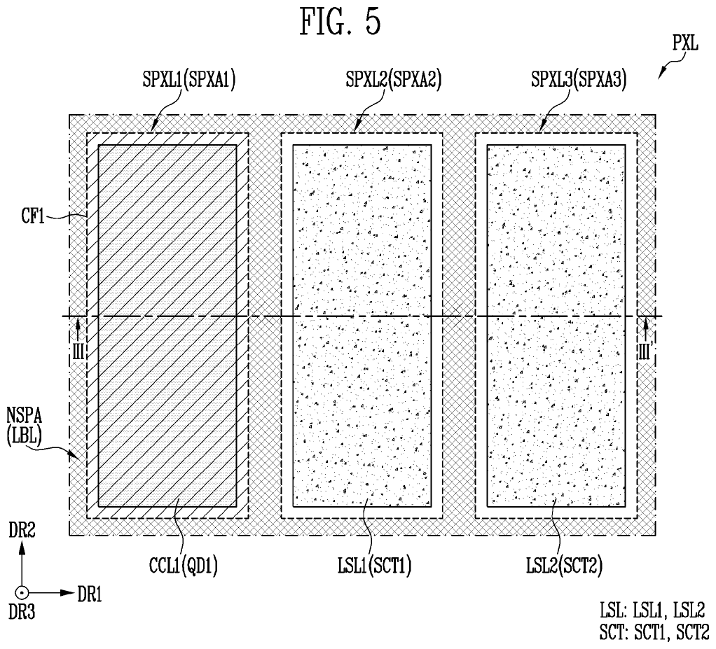

A light emitting element included in each of the sub-pixels SPXL1 to SPXL3 and components disposed on the light emitting element will be described in detail with reference to FIGS. 5 to 14.

The sub-pixels SPXL1 to SPXL3 may be regularly arranged according to a stripe structure, a PENTILE™ structure, or the like. For example, the first sub-pixel SPXL1, the second sub-pixel SPXL2, and the third sub-pixel SPXL3 may be sequentially and repeatedly disposed in a first direction DR1. Also, the first sub-pixel SPXL1, the second sub-pixel SPXL2, and the third sub-pixel SPXL3 may be repeatedly disposed in a second direction DR2. At least one first sub-pixel SPXL1, at least one second sub-pixel SPXL2, and at least one third sub-pixel SPXL3, which are disposed adjacent to each other, may constitute a pixel PXL capable of emitting rays of light of various colors. However, the arrangement structure of the sub-pixels SPXL1 to SPXL3 is not limited thereto, and the sub-pixels SPXL1 to SPXL3 may be arranged in the display area DA in various structures and/or various manners.

The display area DA may be parallel to a plane defined by a first directional axis (e.g., an axis extending in the first direction DR1) and a second directional axis (e.g., an axis extending in the second direction DR2), and a normal direction of the surface, e.g., a thickness direction of the display device DD may be defined as a third direction DR3.

A front surface (or top surface) and a rear surface (or bottom surface) of each of members or parts of the display device DD, described hereinbelow, may be distinguished from each other in the third direction DR3. However, the first to third directions DR1, DR2, and DR3 shown in this embodiment are merely an example. The first to third directions DR1, DR2, and DR3 are relative concepts, and may be changed into other directions. Hereinafter, the first to third directions DR1, DR2, and DR3 are designated by like reference numerals.

In an embodiment, each of the sub-pixels SPXL1 to SPXL3 may be configured as an active pixel. For example, each of the sub-pixels SPXL1 to SPXL3 may include at least one light source (e.g., at least one light emitting element) driven by a control signal (e.g., a predetermined or selectable control signal such as a scan signal and a data signal) and/or a power source (e.g., a predetermined or selectable power source such as a first power source and a second power source). However, this is merely illustrative, and the kind, structure, and/or driving method of the sub-pixels SPXL1 to SPXL3, which can be applied to the display device, are not particularly limited.

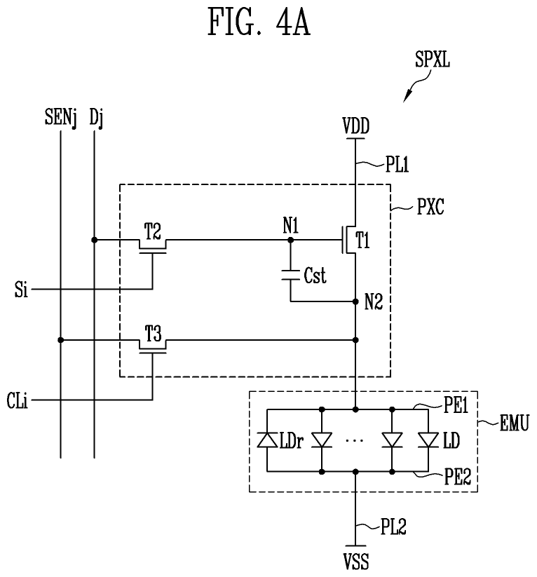

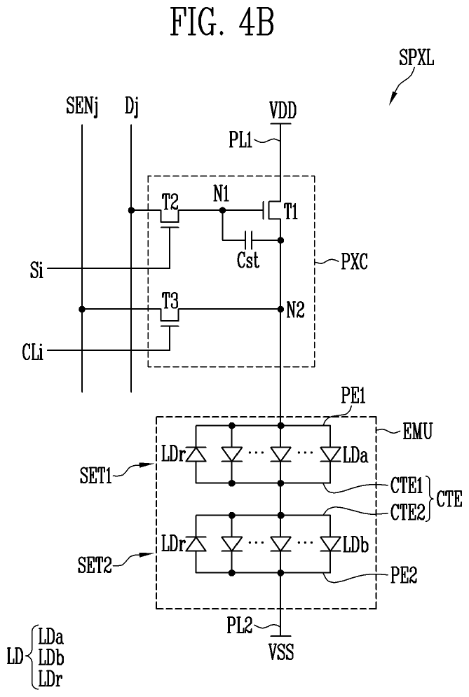

FIG. 4A is a schematic diagram of an equivalent circuit illustrating an example of the pixel (sub-pixel) included in the display device shown in FIG. 3. FIG. 4B is a schematic diagram of an equivalent circuit illustrating another example of the pixel (sub-pixel) included in the display device shown in FIG. 3.

FIGS. 4A and 4B illustrate an electrical connection relationship of components included in the sub-pixel (e.g., the first sub-pixel SPXL1, the second sub-pixel SPXL2, or the third sub-pixel SPXL3) included in the pixel PXL shown in FIG. 3 in accordance with various embodiments.

For example, FIGS. 4A and 4B illustrate an electrical connection relationship of components included in a pixel (e.g., a sub-pixel SPXL) applicable to an active-matrix-type display device (e.g., the display device DD shown in FIG. 3) in accordance with various embodiments. However, the kinds of the components included in the pixel (e.g., the sub-pixel SPXL) applicable to the embodiment of the disclosure are not limited thereto.

Referring to FIGS. 1, 2, 3, 4A, and 4B, the sub-pixel SPXL may include a light emitting part or light emitting unit EMU (hereinafter, “light emitting part”) which generates light with a luminance corresponding to a data signal. Also, the sub-pixel SPXL may selectively further include a pixel circuit PXC for driving the light emitting part EMU.

In embodiments, the light emitting part EMU may include light emitting elements LD electrically connected to each other in parallel between a first power line PL1 electrically connected to a first driving power source VDD to be applied with a voltage of the first driving power source VDD and a second power line PL2 electrically connected to a second driving power source VSS to be applied with a voltage of the second driving power source VSS. For example, the light emitting part EMU may include a first pixel electrode PE1 (or first electrode) electrically connected to the first driving power source VDD via the pixel circuit PXC and the first power line PL1, a second pixel electrode PE2 (or second electrode) electrically connected to the second driving power source VSS through the second power line PL2, and light emitting elements LD electrically connected to each other in parallel in a same direction between the first and second pixel electrodes PE1 and PE2. In embodiments, the first pixel electrode PE1 may be an anode, and the second pixel electrode PE2 may be a cathode.

Each of the light emitting elements LD included in the light emitting part EMU may include an end portion electrically connected to the first driving power source VDD through the first pixel electrode PE1 and another end portion electrically connected to the second driving power source VSS through the second pixel electrode PE2. The first driving power source VDD and the second driving power source VSS may have different potentials. In an example, the first driving power source VDD may be set as a high-potential power source, and the second driving power source VSS may be set as a low-potential power source. A potential difference between the first and second driving power sources VDD and VSS may be set to be equal to or higher than a threshold voltage of the light emitting elements LD during an emission period of the sub-pixel SPXL.

As described above, the light emitting elements LD electrically connected to each other in parallel in a same direction (e.g., a forward direction) between the first pixel electrode PE1 and the second pixel electrode PE2, to which voltages having difference potentials are supplied, may form respective effective light sources.

Each of the light emitting elements LD of the light emitting part EMU may emit light with a luminance corresponding to a driving current supplied through a corresponding pixel circuit PXC. For example, the pixel circuit PXC may supply, to the light emitting unit EMU, a driving current corresponding to a grayscale value of corresponding frame data during each frame period. The driving current supplied to the light emitting part EMU may be divided and flow through each of the light emitting elements LD. Accordingly, the light emitting part EMU can emit light with a luminance corresponding to the driving current while each light emitting element LD is emitting light with a luminance corresponding to a current flowing therethrough.

Although embodiments in which the end portions (or both end portions) of the light emitting elements LD are electrically connected to each other in a same direction between the first and second driving power sources VDD and VSS has been described, but the embodiment of the disclosure is not limited thereto. In embodiments, the light emitting part EMU may further include one or more ineffective light sources, e.g., reverse light emitting elements LDr, in addition to the light emitting elements LD forming the respective effective light sources. The reverse light emitting elements LDr may be electrically connected in parallel together with the light emitting elements LD forming the effective light sources between the first and second pixel electrodes PE1 and PE2, and may be electrically connected to each other between the first and second pixel electrodes PE1 and PE2 in a direction opposite to that in which the light emitting elements LD are electrically connected to each other.

Although a driving voltage (e.g., a predetermined or selectable driving voltage such as a forward driving voltage) is applied between the first and second pixel electrodes PE1 and PE2, the reverse light emitting element LDr maintains an inactivated state, and accordingly, no current substantially flows through the reverse light emitting element LDr.

The pixel circuit PXC may be electrically connected to a scan line Si and a data line Dj of the sub-pixel SPXL. Also, the pixel circuit PXC may be electrically connected to a control line CLi and a sensing line SENj of the pixel PXL. In an example, in case that the sub-pixel SPXL is disposed on an ith row and a jth column of the display area DA, the pixel circuit PXC of the sub-pixel SPXL may be electrically connected an ith scan line Si, a jth data line Dj, an ith control line CLi, and a jth sensing line SENj of the display area DA. Here, i and j may be integers greater than 0.

The pixel circuit PXC may include first to third transistors T1 to T3 and a storage capacitor Cst.

The first transistor T1 is a driving transistor for controlling a driving current applied to the light emitting part EMU, and may be electrically connected between the first driving power source VDD and the light emitting part EMU. Specifically, a first terminal of the first transistor T1 may be electrically connected (or coupled) to the first driving power source VDD through the first power line PL1, a second terminal of the first transistor T1 may be electrically connected to a second node N2, and a gate electrode of the first transistor T1 may be electrically connected to a first node N1. The first transistor T1 may control an amount of driving current applied to the light emitting part EMU through the second node N2 from the first driving power source VDD according to a voltage applied to the first node N1. In an embodiment, the first terminal of the first transistor T1 may be a drain electrode, and the second terminal of the first transistor T1 may be a source electrode. However, the disclosure is not limited thereto. In embodiments, the first terminal may be a source electrode, and the second terminal may be a drain electrode.

The second transistor T2 is a switching transistor which selects a sub-pixel SPXL in response to a scan signal and activates the sub-pixel SPXL, and may be electrically connected between the data line Dj and the first node N1. A first terminal of the second transistor T2 may be electrically connected to the data line Dj, a second terminal of the second transistor T2 may be electrically connected to the first node N1, and a gate electrode of the second transistor T2 may be electrically connected to the scan line Si. The first terminal and the second terminal of the second transistor T2 are different terminals. For example, in case that the first terminal is a drain electrode, the second terminal may be a source electrode.

The second transistor T2 may be turned on in case that a scan signal having a gate-on voltage (e.g., a high-level voltage) is supplied from the scan line Si, to electrically connect the data line Dj and the first node N1 to each other. The first node N1 is a point at which the second terminal of the second transistor T2 and the gate electrode of the first transistor T1 are electrically connected to each other, and the second transistor T2 may transfer a data signal to the gate electrode of the first transistor T1.

The third transistor T3 may electrically connect the first transistor T1 to the sensing line SENj, to acquire a sensing signal through the sensing line SENj and to detect a characteristic of the sub-pixel SPXL, including a threshold voltage of the first transistor T1, or the like, by using the sensing signal. Information on the characteristic of the sub-pixel SPXL may be used to convert image data such that a characteristic deviation between pixels PXL can be compensated for. A second terminal of the third transistor T3 may be electrically connected to the second terminal of the first transistor T1, a first terminal of the third transistor T3 may be electrically connected to the sensing line SENj, and a gate electrode of the third transistor T3 may be electrically connected to the control line CLi. Also, the first terminal of the third transistor T3 may be electrically connected to an initialization power source. The third transistor T3 is an initialization transistor capable of initializing the second node N2. The third transistor T3 may be turned on in case that a sensing control signal is supplied from the control line CLi, to transfer a voltage of the initialization power source to the second node N2. Accordingly, a second storage electrode of the storage capacitor Cst, which is electrically connected to the second node N2, may be initialized.

A first storage electrode of the storage capacitor Cst may be electrically connected to the first node N1, and the second storage electrode of the storage capacitor Cst may be electrically connected to the second node N2. The storage capacitor Cst may be charged with a data voltage corresponding to the data signal supplied to the first node N1 during a frame period. Accordingly, the storage capacitor Cst may store a voltage corresponding to the difference between a voltage of the gate electrode of the first transistor T1 and a voltage of the second node N2.

Although FIG. 4A illustrates an embodiment in which the light emitting elements LD constituting the light emitting part EMU are all electrically connected to each other in parallel, the embodiment of the disclosure is not limited thereto. In embodiments, the light emitting part EMU may be configured to include at least one serial stage (or stage) including light emitting elements LD electrically connected in parallel to each other. In embodiments, the light emitting part EMU may be configured in a series or parallel hybrid structure as shown in FIG. 4B.

For example, referring to FIG. 4B, the light emitting part EMU may include first and second serial stages SET1 and SET2, which are sequentially electrically connected to each other between the first and second driving power sources VDD and VSS. Each of the first and second serial stages SET1 and SET2 may include two electrodes PE1 and CTE1 or CTE2 and PE2 constituting an electrode pair of the corresponding serial stage and light emitting elements LD electrically connected to each other in parallel in a same direction between the two electrodes PE1 and CTE1 or CTE2 and PE2.

The first serial stage SET1 (or first stage) includes a first pixel electrode PE1 and a first intermediate electrode CTE1, and include at least one first sub-light emitting element LDa electrically connected between the first pixel electrode PE1 and the first intermediate electrode CTE1. In embodiments, the first serial stage SET1 may further include a reverse light emitting element LDr electrically connected in the opposite direction of the direction in which the first sub-light emitting element LDa is electrically connected, between the first pixel electrode PE1 and the first intermediate electrode CTE1.

The second serial stage SET2 (or second stage) may include a second intermediate electrode CTE2 and a second pixel electrode PE2, and include at least one second sub-light emitting element LDb electrically connected between the second intermediate electrode CTE2 and the second pixel electrode PE2. In embodiments, the second serial stage SET2 may further include a reverse light emitting element LDr electrically connected in the opposite direction of the direction in which the second sub-light emitting element LDb is electrically connected, between the second intermediate electrode CTE2 and the second pixel electrode PE2.

The first intermediate electrode CTE1 and the second intermediate electrode CTE2 may be electrically and/or physically connected to each other. The first intermediate electrode CTE1 and the second intermediate electrode CTE2 may constitute an intermediate electrode CTE electrically connecting the first serial stage SET1 and the second serial stage SET2, which are consecutive, to each other.

In the above-described embodiment, the first pixel electrode PE1 of the first serial stage SET1 may be an anode of each sub-pixel SPXL, and the second pixel electrode PE2 of the second serial stage SET2 may be a cathode of the corresponding sub-pixel SPXL.

As described above, the light emitting part EMU of the sub-pixel SPXL, which includes first and second serial stages SET1 and SET2 (or light emitting elements LD) electrically connected to each other in a series/parallel hybrid structure, can easily control driving current/voltage conditions to be suitable for specifications of a product to which the light emitting part EMU is applied.

In particular, the light emitting part EMU of the sub-pixel SPXL, which includes the first and second serial stages SET1 and SET2 (or the light emitting elements LD) electrically connected to each other in the series/parallel hybrid structure, can decrease a driving current, as compared with a light emitting part EMU having a structure in which light emitting elements LD are electrically connected to each other only in parallel. Also, the light emitting part EMU of the sub-pixel SPXL, which includes the first and second serial stages SET1 and SET2 (or the light emitting elements LD) electrically connected to each other in the series/parallel hybrid structure, can decrease a driving voltage applied to ends of the light emitting part EMU, as compared with a light emitting part EMU having a structure in which the same number of light emitting elements LD are electrically connected to each other in series. Further, the light emitting part EMU of the sub-pixel SPXL, which includes the first and second serial stages SET1 and SET2 (or the light emitting elements LD) electrically connected to each other in the series/parallel hybrid structure, can include a larger number of light emitting elements LD between the same number of contact electrodes PE1, CTE1, CTE2, and PE2, as compared with a light emitting part EMU having a structure in which serial stages (or stages) are all electrically connected to each other in series. Thus, the light emission efficiency of light emitting elements LD can be improved. Although a defect occurs in a specific serial stage (or stage), the ratio of light emitting element LD which do not emit light due to the defect can be relatively decreased. Accordingly, deterioration of the light emission efficiency of light emitting elements LD can be reduced.

Although FIGS. 4A and 4B illustrate embodiments in which the first, second, and third transistors T1, T2, and T3 included in the pixel circuit PXC are all implemented as an N-type transistor, the embodiment of the disclosure is not limited thereto. For example, at least one of the above-described first, second, and third transistors T1, T2, and T3 may be changed to a P-type transistor. Also, although FIGS. 4A and 4B illustrate embodiments in which the light emitting part EMU is electrically connected between the pixel circuit PXC and the second driving power source VSS, the light emitting part EMU may also be electrically connected between the first driving power source VDD and the pixel circuit PXC.

The structure of the pixel circuit PXC may be variously modified and embodied. In an example, the pixel circuit PXC may additionally further include at least one transistor element such as a transistor element for initializing the first node N1 and/or a transistor element for controlling an emission time of the light emitting elements LD, or other circuit elements such as a boosting capacitor for boosting the voltage of the first node N1.

The structure of a sub-pixel SPXL applied to the disclosure is not limited to the embodiments shown in FIGS. 4A and 4B, and the corresponding sub-pixel SPXL may have various structures. For example, each sub-pixel SPXL may be configured in a passive type light emitting display device, or the like. The pixel circuit PXC may be omitted, and end portions of the light emitting element LD included in the light emitting part EMU may be directly electrically connected to the scan line Si, the data line Dj, the first power line PL1 to which the voltage of the first driving power source VDD is applied, the second power line PL2 to which the voltage of the second driving power source VSS is applied, and/or a control line.

FIG. 5 is a schematic plan view illustrating an example of the pixel included in the display device shown in FIG. 3.

FIG. 5 illustrates a structure for defining sub-pixel areas SPXA1 to SPXA3 of the sub-pixels SPXL1 to SPXL3 included in the pixel PXL.

Although FIG. 5 illustrates an embodiment of a structure in which the sub-pixels SPXL1 to SPXL3 are arranged in the first direction DR1 as described with reference to FIG. 3, this is merely illustrative, and the embodiment of the disclosure is not limited thereto.

Referring to FIGS. 3 and 5, the pixel PXL may include sub-pixels SPXL1 to SPXL3 each emitting light of a color (e.g., a predetermined or selectable color). For example, the pixel PXL may include a first sub-pixel SPXL1 emitting light of a first color (e.g., red), a second sub-pixel SPXL2 emitting light of a second color (e.g., green), and a third sub-pixel SPXL3 emitting light of a third color (e.g., blue).

Each of the sub-pixels SPXL1 to SPXL3 may include a sub-pixel area. For example, the first sub-pixel SPXL1 may include a first sub-pixel area SPXA1, the second sub-pixel SPXL2 may include a second sub-pixel area SPXA2, and the third sub-pixel SPXL3 may include a third sub-pixel area SPXA3.

The sub-pixels SPXL1 to SPXL3 may respectively correspond to the sub-pixel areas SPXA1 to SPXA3. For example, rays of light of different colors, which are viewed from the outside, may be provided (or emitted) in the respective sub-pixel areas SPXA1 to SPXA3.

For example, light of the first color may be emitted (or provided) from the first sub-pixel SPXL1 in the first sub-pixel area SPXA1. Light of the second color may be emitted (or provided) from the second sub-pixel SPXL2 in the second sub-pixel area SPXA2. Light of the third color may be emitted (or provided) from the third sub-pixel SPXL3 in the third sub-pixel area SPXA3. In an embodiment, the light of the first color may be viewed from the outside corresponding to the first sub-pixel area SPXA1, the light of the second color may be viewed from the outside corresponding to the second sub-pixel area SPXA2, and the light of the third color may be viewed from the outside corresponding to the third sub-pixel area SPXA3. However, the disclosure is not limited thereto.

In an embodiment, as described with reference to FIG. 3, the first sub-pixel SPXL1 and the third sub-pixel SPXL3 among the sub-pixels SPXL1 to SPXL3 may include a light emitting element (e.g., a first light emitting element) emitting light of the third color (e.g., light of blue). The first sub-pixel SPXL1 may include a color conversion layer (e.g., a first color conversion layer CCL1) and a color filter layer (e.g., a first color filter CF1), which are disposed above the light emitting element (e.g., the first light emitting element), to emit light of the first color (e.g., light of red). The second sub-pixel SPXL2 may include a light emitting element (e.g., a second light emitting element) emitting light of the second color (e.g., light of green).

In an embodiment, the pixel PXL may selectively include a light blocking layer LBL (or light blocking pattern). The light blocking layer LBL may include a light blocking material for preventing a light leakage defect in which light (or beam) is leaked between adjacent sub-pixels among the sub-pixels SPXL1 to SPXL3. For example, the light blocking layer LBL may include a black matrix. The light blocking layer LBL may prevent color mixture of rays of light respectively emitted from the adjacent sub-pixels SPXL1 to SPXL3.

In embodiments, the sub-pixel areas SPXA1 to SPXA3 may be defined by the light blocking layer LBL. For example, the sub-pixel areas SPXA1 to SPXA3 may be defined as areas in which the light blocking layer LBL is not disposed. For example, the sub-pixel areas SPXA1 to SPXA3 may not overlap an area in which the light blocking layer LBL is disposed in a plan view (e.g., when viewed on a plane defined by the first direction DR1 and the second direction DR2). The area in which the light blocking layer LBL is disposed may be defined as a non-sub-pixel area NSPA. For example, a patterning position of the light blocking layer LBL may be adjusted, so that a range of the sub-pixel areas SPXA1 to SPXA3 is appropriately adjusted.

In an embodiment, the first sub-pixel SPXL1 may include the first color conversion layer CCL1 and the first color filter CF1. Light (e.g., light of the third color) emitted from the first light emitting element included in the first sub-pixel SPXL1 may be provided to the first color conversion layer CCL1, and first color conversion particles QD1 of the first color conversion layer CCL1 may convert light of the third color (e.g., blue), emitted from the first light emitting element, into light of the first color (e.g., red). The color-converted light may be provided to the first color filter CF1, and the first sub-pixel SPXL1 may emit light of the first color (e.g., red), based on the light provided to the first color filter CF1 to be transmitted through the first color filter CF1.

The first color filter CF1 may be disposed (or provided) corresponding to the first sub-pixel area SPXA1 of the first sub-pixel SPXL1. The first color filter CF1 may allow light advancing toward the same to be selectively transmitted therethrough. For example, the first color filter CF1 is a color filter of the first color (e.g., a red color filter) and may allow light of the first color (e.g., red) to be selectively transmitted therethrough.

In an embodiment, each of the second sub-pixel SPXL2 and the third sub-pixel SPXL3 may include a light scattering layer LSL including a light scattering particle SCT. For example, the second sub-pixel SPXL2 may include a first light scattering layer LSL1 including a first light scattering particle SCT1, and the third sub-pixel SPXL3 may include a second light scattering layer LSL2 including a second light scattering particle SCT2.

The light scattering layer LSL may be used to allow light, emitted from a light emitting element included in each sub-pixel, to be more efficiently emitted. For example, the scattering particle of the light scattering layer LSL may include a light scattering material or a light scattering particle, which scatters at least a portion of transmitted light. The light scattering particle SCT may allow light to be scattered in a random direction regardless of the incident direction of incident light while not substantially changing a peak wavelength of the incident light (e.g., while not converting a color of the incident light).

Light (e.g., light of the second color) emitted from the second light emitting element included in the second sub-pixel SPXL2 may be provided to the first light scattering layer LSL1, and first light scattering particles SCT1 of the first light scattering layer LSL1 may scatter light of the second color (e.g., green) emitted from the second light emitting element without color conversion. Accordingly, the second sub-pixel SPXL2 may emit light of the second color (e.g., green), based on the light provided to the first light scattering layer LSL1 to be transmitted through the first light scattering layer LSL1.

Light (e.g., light of the third color) emitted from the first light emitting element included in the third sub-pixel SPXL3 may be provided to the second light scattering layer LSL2, and second light scattering particles SCT2 of the second light scattering layer LSL2 may scatter light of the third color (e.g., blue) emitted from the first light emitting element without color conversion. Accordingly, the third sub-pixel SPXL3 may emit light of the third color (e.g., blue), based on the light provided to the second light scattering layer LSL2 to be transmitted through the second light scattering layer LSL2.

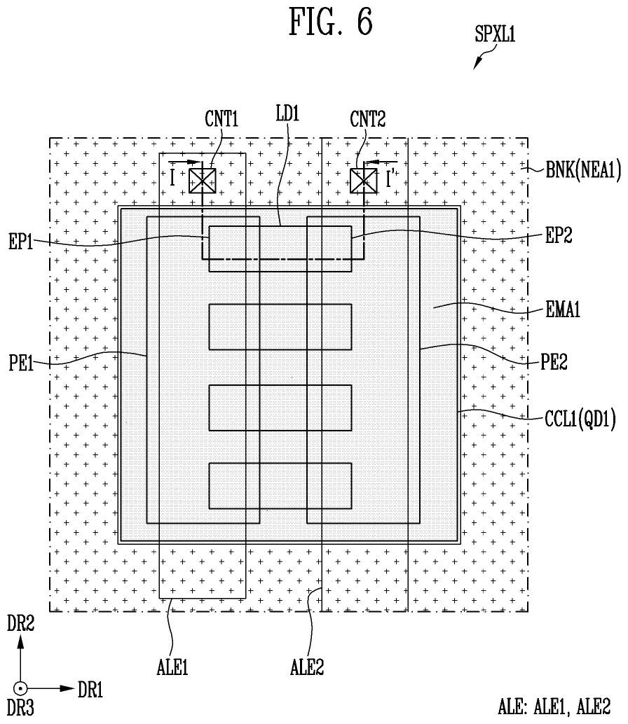

FIG. 6 is a schematic plan view illustrating an example of the first sub-pixel included in the pixel shown in FIG. 5.

Referring to FIGS. 3, 4A, 5, and 6, the first sub-pixel SPXL1 (or the first sub-pixel area SPXA1) may include a first emission area EMA1 and a first non-emission area NEA1 The first sub-pixel SPXL1 may include a first alignment electrode ALE1, a second alignment electrode ALE2, first light emitting elements LD1, a first pixel electrode PE1, and a second pixel electrode PE2.

The first light emitting elements LD1 may not be disposed in the first non-emission area NEA1. A portion of the first non-emission area NEA1 may overlap a bank BNK in a plan view (e.g., when viewed on a plane defined by the first direction DR1 and the second direction DR2). For example, the bank BNK may define the first emission area EMA1 and the first non-emission area NEA1. In a plan view, the bank BNK may overlap the first non-emission area NEA. For example, the bank BNK may be a pixel defining layer or a dam structure, which defines the first emission area EMA1 to which the first light emitting elements LD1 are to be supplied in a process of supplying the first light emitting elements LD1 to the first sub-pixel SPXL1.

For example, the bank BNK1 may surround at least a portion of the first emission area EMA.

An alignment electrode ALE is electrodes for aligning the first light emitting elements LD1. The alignment electrode ALE may include the first alignment electrode ALE1 and the second alignment electrode ALE2.

The alignment electrode ALE may have a single-layer structure or a multi-layer structure. For example, the alignment electrode ALE may include at least one reflective electrode layer including a reflective conductive material, and may selectively further include at least one transparent electrode layer and/or at least one conductive capping layer. In embodiments, the alignment electrode ALE may include at least one of silver (Al), magnesium (Mg), aluminum (Al), platinum (Pt), palladium (Pd), gold (Au), nickel (Ni), neodymium (Nd), iridium (Ir), chromium (Cr), titanium (Ti), and any alloy thereof. However, the embodiment of the disclosure is not limited to the above-described example. For example, the alignment electrode ALE may include at least one of various materials having reflexibility.

The first light emitting elements LD1 may be disposed on the alignment electrode ALE. In embodiments, the first light emitting elements LD1 may be disposed between the first alignment electrode ALE1 and the second alignment electrode ALE2. The first light emitting elements LD1 may be aligned between the first alignment electrode ALE1 and the second alignment electrode ALE2.

In embodiments, the first light emitting elements LD1 may be aligned in various manners. For example, FIG. 6 illustrates an embodiment in which the first light emitting elements LD1 are aligned in parallel between the first alignment electrode ALE1 and the second alignment electrode ALE2. However, this is merely illustrative, and the embodiment of the disclosure is not limited thereto. For example, the first light emitting elements LD1 may be aligned in a series or series/parallel hybrid structure, and the number of parts electrically connected to each other in series and/or parallel is not particularly limited.

The first alignment electrode ALE1 and the second alignment electrode ALE2 may be spaced apart from each other. For example, the first alignment electrode ALE1 and the second alignment electrode ALE2 may be spaced apart from each other in the first direction DR1 in the first emission area EMA1, and each of the first alignment electrode ALE1 and the second alignment electrode ALE2 may extend in the second direction DR2.

The first alignment electrode ALE1 and the second alignment electrode ALE2 may be respectively supplied (or provided) with a first alignment signal and a second alignment signal in a process of aligning the first light emitting elements LD1. For example, an ink including the first light emitting elements LD1 may be supplied (or provided) to the first emission area EMA1 in which the bank BNK is defined, the first alignment signal may be supplied to the first alignment electrode ALE1, and the second alignment signal may be supplied to the second alignment electrode ALE2. The first light emitting elements LD1 may be aligned according to an electric field formed by the first alignment signal and the second alignment signal.

In an embodiment, the first alignment electrode ALE1 may be electrically connected to a first transistor T1 through a first contact hole CNT1.

In an embodiment, the second alignment electrode ALE2 may be electrically connected to a power line (e.g., the second power line PL2 shown in FIG. 4A) through a second contact hole CNT2.

The positions of the first contact hole CNT1 and the second contact hole CNT2 are not limited to positions shown in FIG. 6, and may be appropriately and variously changed.

A first end portion EP1 of the first light emitting element LD1 may be adjacent to the first alignment electrode ALE1, and a second end portion EP2 of the first light emitting element LD1 may be adjacent to the second alignment electrode ALE2.

In embodiments, the first end portion EP1 of each of the first light emitting elements LD1 may be electrically connected to the first alignment electrode ALE1 through the first pixel electrode PE1. In another embodiment, the first end portion EP1 of each of the first light emitting elements LD1 may be electrically connected directly to the first alignment electrode ALE1.

In still another embodiment, the first end portion EP1 of each of the first light emitting elements LD1 is electrically connected to only the first pixel electrode PE1, and may not be electrically connected to the first alignment electrode ALE1. The first pixel electrode PE1 may be electrically connected to the transistor T1 thereunder through a contact hole while avoiding the first alignment electrode ALE1.

Similarly, the second end portion EP2 of each of the first light emitting elements LD1 may be electrically connected to the second alignment electrode ALE2 and the second power line PL2 through the second pixel electrode PE2. In another embodiment, the second end portion EP2 of each of the first light emitting elements LD1 may be electrically connected directly to the second alignment electrode ALE2.

In still another embodiment, the second end portion EP2 of each of the first light emitting elements LD1 is electrically connected to only the second pixel electrode PE2, and may not be electrically connected to the second alignment electrode ALE2.

The first pixel electrode PE1 may be disposed on the first end portions EP1 of the first light emitting elements LD1 to be electrically connected to the first end portions EP1. In an embodiment, the first pixel electrode PE1 may be disposed on the first alignment electrode ALE1 to be electrically connected to the first alignment electrode ALE1.

The second pixel electrode PE2 may be disposed on the second end portions EP2 of the first light emitting elements LD1 to be electrically connected to the second end portions EP2. In an embodiment, the second pixel electrode PE2 may be disposed on the second alignment electrode ALE2 to be electrically connected to the second alignment electrode ALE2.

In an embodiment, the first sub-pixel SPXL1 may further include a first color conversion layer CCL1 including first color conversion particles QD1.

The first color conversion layer CCL1 may be disposed to correspond to the first emission area EMA1 of the first sub-pixel SPXL1. For example, the first color conversion layer CCL1 may be located above the first light emitting elements LD1 disposed in the first emission area EMA1.

As described with reference to FIG. 5, the first sub-pixel SPXL1 may include a color filter (e.g., the first color filter CF1 shown in FIG. 5). For example, the first color filter CF1 of the first sub-pixel SPXL1 may be located on the top of the first color conversion layer CCL1.

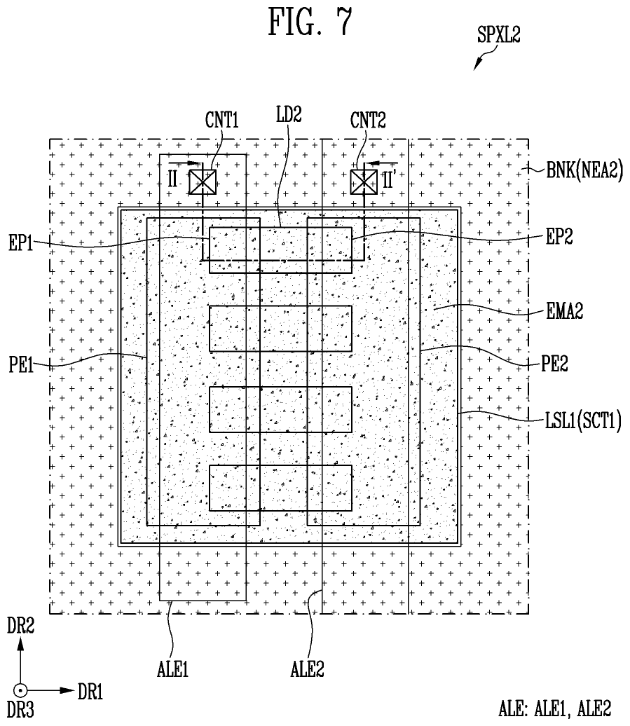

FIG. 7 is a schematic plan view illustrating an example of the second sub-pixel included in the pixel shown in FIG. 5.

The second sub-pixel SPXL2 shown in FIG. 7 is substantially identical or similar to the first sub-pixel SPXL1 shown in FIG. 6, except that the second sub-pixel SPXL2 does not include any color conversion layer but includes a light scattering layer (e.g., a first light scattering layer LSL1), and therefore, repetitive descriptions will not be provided. Portions not particularly described in FIG. 7 are substantially identical to the portions described with reference to FIG. 6. In FIG. 7, identical or similar reference numerals may represent components subsequently similar to the components described with reference to FIG. 6.

Referring to FIGS. 3, 5, 6, and 7, the second sub-pixel SPXL2 (or the second sub-pixel area SPXA2) may include a second emission area EMA2 and a second non-emission area NEA2. The second sub-pixel SPXL2 may include a first alignment electrode ALE1, a second alignment electrode ALE2, second light emitting elements LD2, a first pixel electrode PE1, and a second pixel electrode PE2.

In an embodiment, the second sub-pixel SPXL2 may further include the first light scattering layer LSL1 including first light scattering particles SCT1.

The first light scattering layer LSL1 may be disposed to correspond to the second emission area EMA2 of the second sub-pixel SPXL2. For example, the first light scattering layer LSL1 may be located above second light emitting elements LD2 disposed in the second emission area EMA2.

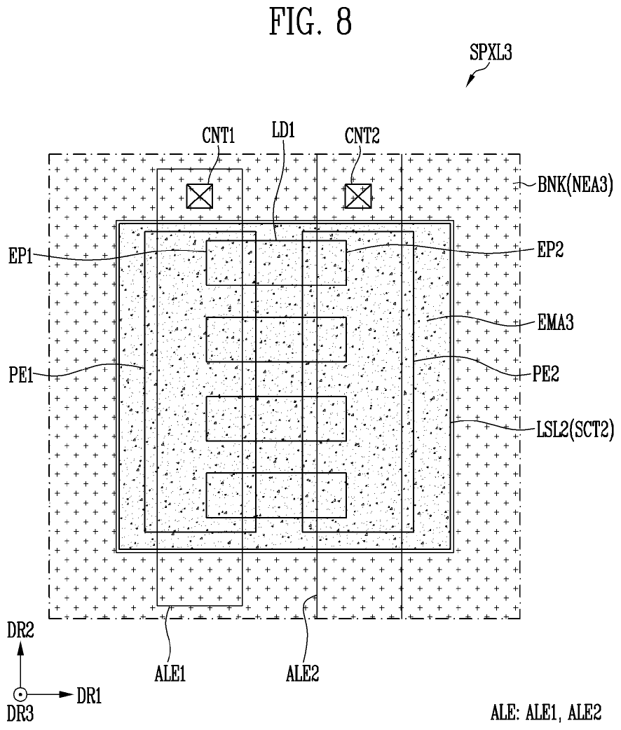

FIG. 8 is a schematic plan view illustrating an example of the third sub-pixel included in the pixel shown in FIG. 5.

The third sub-pixel SPXL3 shown in FIG. 8 is substantially identical or similar to the first sub-pixel SPXL1 shown in FIG. 6, except that the third sub-pixel SPXL3 does not include any color conversion layer but includes a light scattering layer (e.g., a second light scattering layer LSL2), and therefore, repetitive descriptions will not be provided. Portions not particularly described in FIG. 8 are substantially identical to the portions described with reference to FIG. 6. In FIG. 8, identical or similar reference numerals may represent components subsequently similar to the components described with reference to FIG. 6.

Referring to FIGS. 3, 5, 6, and 8, the third sub-pixel SPXL3 (or the third sub-pixel area SPXA3) may include a third emission area EMA3 and a third non-emission area NEA3. The third sub-pixel SPXL3 may include a first alignment electrode ALE1, a second alignment electrode ALE2, first light emitting elements LD1, a first pixel electrode PE1, and a second pixel electrode PE2.

In an embodiment, the third sub-pixel SPXL3 may further include the second light scattering layer LSL2 including second light scattering particles SCT2.

The second light scattering layer LSL2 may be disposed to correspond to the third emission area EMA3 of the third sub-pixel SPXL3. For example, the second light scattering layer LSL2 may be located above the first light emitting elements LD1 disposed in the third emission area EMA3.

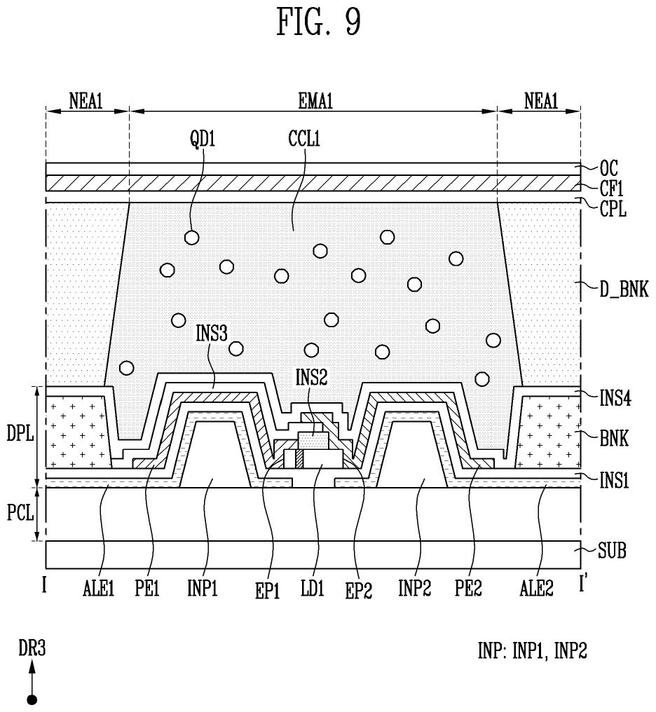

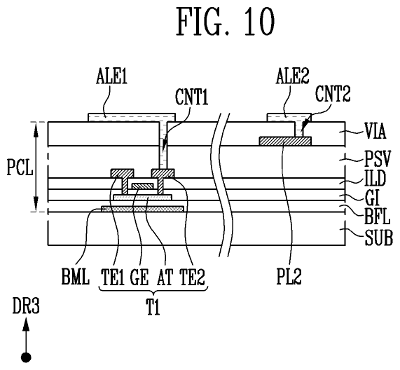

FIG. 9 is a schematic sectional view illustrating an example taken along line I-I′ shown in FIG. 6. FIG. 10 is a schematic sectional view illustrating an example of a pixel circuit layer of the first sub-pixel shown in FIG. 6. FIGS. 9 and 10 illustrate a sectional structure of the first sub-pixel SPXL1 described with reference to FIG. 6.

Referring to FIGS. 3, 4A, 5, 6, and 9, the first sub-pixel SPXL1 may include a substrate SUB, a pixel circuit layer PCL, a display element layer DPL, and a color filter layer (e.g., a first color filter CF1). In an embodiment, the first sub-pixel SPXL1 may further include a capping layer CPL disposed between the display element layer DPL and the color filter layer and an overcoat layer OC disposed on the color filter layer.

The substrate SUB may form a base member of the display device DD. The substrate SUB may be a rigid or flexible substrate or film. The substrate SUB may include a transparent insulating material to enable light to be transmitted therethrough.

In an embodiment, the substrate SUB may be a rigid substrate. For example, the rigid substrate may be at least one of a glass substrate, a quartz substrate, a glass ceramic substrate, and a crystalline glass substrate.

In an embodiment, the substrate SUB may be a flexible substrate. The flexible substrate may be at least one of a film substrate and a plastic substrate, which include a polymer organic material. However, the material forming the substrate SUB may be variously changed, and include fiber reinforced plastic (FRP), and the like.

The pixel circuit layer PCL may be disposed on the substrate SUB.

Further referring to FIG. 10, the pixel circuit layer PCL may include a lower auxiliary electrode BML, a buffer layer BFL, a first transistor T1, a gate insulating layer GI, an interlayer insulating layer ILD, a passivation layer PSV, and a via layer VIA. For convenience of description, FIG. 10 illustrates the first transistor T1 among circuit elements.

The lower auxiliary electrode BML may be disposed on the substrate SUB. The lower auxiliary electrode BML may serve as a path through which an electrical signal is moved. In embodiments, a portion of the lower auxiliary electrode BML may overlap the first transistor T1 in a plan view.

The buffer layer BFL may be disposed on the substrate SUB. The buffer layer BFL may cover the lower auxiliary electrode BML. The buffer layer BFL may prevent an impurity from being diffused from the outside. The buffer layer BFL may include at least one of silicon oxide (SiOₓ), silicon nitride (SiNₓ), silicon oxynitride (SiOₓN_{y}), aluminum oxide (AlOₓ), and titanium oxide (TiOₓ).

The first transistor T1 may be electrically connected to a light emitting element (e.g., a first light emitting element LD1). The first transistor T1 may include an active layer AT, a first transistor electrode TE1, a second transistor electrode TE2, and a gate electrode GE.

The active layer AT may include a semiconductor layer. The active layer AT may be disposed on the buffer layer BFL. The active layer AT may include at least one of poly-silicon, Low Temperature Polycrystalline Silicon (LTPS), amorphous silicon, and an oxide semiconductor.

The active layer AT may include a first contact region contacting the first transistor electrode TE1 and a second contact region contacting the second transistor electrode TE2. The first contact region and the second contact region may correspond to a semiconductor pattern doped with an impurity. A region between the first contact region and the second contact region may be a channel region. The channel region may correspond to an intrinsic semiconductor pattern undoped with an impurity.

The gate electrode GE may be disposed on the gate insulating layer GI. A position of the gate electrode GE may correspond to that of the channel region of the active layer AT. For example, the gate electrode GE may be disposed on the channel region of the active layer AT with the gate insulating layer GI interposed therebetween.

The gate insulating layer GI may be disposed on the active layer AT. The gate insulating layer GI may include at least one of silicon oxide (SiOₓ), silicon nitride (SiNₓ), silicon oxynitride (SiOₓN_{y}), aluminum oxide (AlOₓ), and titanium oxide (TiOₓ).

The interlayer insulating layer ILD may be disposed on the gate electrode GE. The interlayer insulating layer ILD may include at least one of silicon oxide (SiOₓ), silicon nitride (SiNₓ), silicon oxynitride (SiOₓN_{y}), aluminum oxide (AlOₓ), and titanium oxide (TiOₓ).

The first transistor electrode TE1 and the second transistor electrode TE2 may be disposed on the interlayer insulating layer ILD. The first transistor electrode TE1 may contact the first contact region of the active layer AT while penetrating the gate insulating layer GI and the interlayer insulating layer ILD, and the second transistor electrode TE2 may contact the second contact region of the active layer AT while penetrating the gate insulating layer GI and the interlayer insulating layer ILD. In an example, the first transistor electrode TE1 may be a drain electrode, and the second transistor electrode TE2 may be a source electrode. However, the disclosure is not limited thereto.

In an embodiment, the second transistor electrode TE2 may be electrically connected to a first alignment electrode ALE through a first contact hole CNT1 penetrating the via layer VIA and the passivation layer PSV.

The passivation layer PSV may be disposed on the interlayer insulating layer ILD. The passivation layer PSV may include an organic material and/or an inorganic material. The passivation layer PSV may prevent diffusion of an impurity.

In an embodiment, a signal line such as a second power line PL2 may be disposed on the passivation layer PSV. However, this is merely illustrative, and the second power line PL2 may be disposed on the interlayer insulating layer ILD.

The via layer VIA covering the second power line PL2 may be disposed on the passivation layer PSV. The via layer VIA may include an organic insulating layer, an inorganic insulating layer, or an organic insulating layer disposed on an inorganic insulating layer. The inorganic insulating layer may include at least one of silicon oxide (SiOₓ), silicon nitride (SiNₓ), silicon oxynitride (SiOₓN_{y}), and metal oxide such as aluminum oxide (AlOₓ).

The organic insulating layer may include, for example, at least one of acryl resin, epoxy resin, phenolic resin, polyamide resin, polyimide resin, unsaturated polyester resin, poly-phenylene ether resin, poly-phenylene sulfide resin, and benzocyclobutene (BCB).

In an embodiment, the second power line PL2 may be electrically connected to the second alignment electrode ALE2 through a second contact hole CNT2 penetrating the via layer VIA.

Referring back to FIG. 9, the display element layer DPL may be provided on the via layer VIA. The display element layer DPL may include an insulating pattern INP (e.g., a first insulating pattern INP1 and a second insulating pattern INP2), the first alignment electrode ALE1, the second alignment electrode ALE2, a bank BNK, the first light emitting element LD1, a first pixel electrode PE1, a second pixel electrode PE2, a first insulating layer INS1, a second insulating layer INS2, a third insulating layer INS3, and a fourth insulating layer INS4.

The first insulating pattern INP1 and the second insulating pattern INP2 may be disposed on the via layer VIA. The first insulating pattern INP1 and the second insulating pattern INP2 may protrude in a thickness direction of the substrate SUB (e.g., the third direction DR3). The first insulating pattern INP1 and the second insulating pattern INP2 may include an organic material and/or an inorganic material.

The first light emitting element LD1 may be disposed between the first insulating pattern INP1 and the second insulating pattern INP2. For example, the first and second insulating patterns INP1 and INP2 may define spaces in which light emitting elements LD are accommodated and arranged.

The first alignment electrode ALE1 and the second alignment electrode ALE2 may be disposed on the via layer VIA. A portion of the first alignment electrode ALE1 may be disposed on the first insulating pattern INP1, and a portion of the second alignment electrode ALE2 may be disposed on the second insulating pattern INP2. Each of the first alignment electrode ALE1 and the second alignment electrode ALE2 may serve as a reflective partition wall.

In an embodiment, the first alignment electrode ALE1 may be electrically connected to a first end portion EP1 of the first light emitting element LD1 through the first pixel electrode PE1, and the second alignment electrode ALE2 may be electrically connected to a second end portion EP2 of the first light emitting element LD1 through the second pixel electrode PE2. However, this is merely illustrative, and at least one of the first alignment electrode ALE1 and the second alignment electrode ALE2 may be electrically insulated from the first light emitting element LD1.

The first and second alignment electrodes ALE1 and ALE2 may include a conductive material. For example, the first and second alignment electrodes ALE1 and ALE2 may include at least one of silver (Al), magnesium (Mg), aluminum (Al), platinum (Pt), palladium (Pd), gold (Au), nickel (Ni), neodymium (Nd), iridium (Ir), chromium (Cr), titanium (T1), and any alloy thereof. However, the disclosure is not limited to the above-described example.

The first insulating layer INS1 may be disposed on the via layer VIA. The first insulating layer INS1 may cover the first and second alignment electrodes ALE1 and ALE2. The first insulating layer INS1 may stabilize connection between electrode components, and reduce external influence. The first insulating layer INS1 may include at least one of silicon oxide (SiOₓ), silicon nitride (SiNₓ), silicon oxynitride (SiOₓN_{y}), aluminum oxide (AlOₓ), and titanium oxide (TiOₓ).

The bank BNK may be disposed on the first insulating layer INS1. The bank BNK may protrude in the thickness direction of the substrate SUB (e.g., the third direction DR3). The bank BNK may surround the first emission area EMA1. In an embodiment, the bank BNK may include an organic material and/or an inorganic material. The bank BNK may correspond to the first non-emission area NEA1.

In an embodiment, a thickness of the bank BNK may be about 1 μm. For example, the thickness of the bank BNK may be about ¼ of a thickness of the first color conversion layer CCL1. However, this is merely illustrative, and the embodiment of the disclosure is not limited thereto.

The first light emitting element LD1 may be disposed on the first insulating layer INS1. The first light emitting element LD1 may overlap a portion of the first alignment electrode ALE1 and a portion of the second alignment electrode ALE2.

The second insulating layer INS2 may be disposed on the first light emitting element LD1. The second insulating layer INS2 may cover an active layer (e.g., the active layer 12 shown in FIG. 1) of the first light emitting element LD1. Also, the second insulating layer INS2 may prevent a short circuit between adjacent electrodes (e.g., the first pixel electrode PE1 and the second pixel electrode PE2). The second insulating layer INS2 may include an organic material or an inorganic material.

The first pixel electrode PE1 may contact the first end portion EP1 of the first light emitting element LD1, and be disposed on the first insulating layer INS1. The first pixel electrode PE1 may be an anode electrode electrically connected to the first transistor T1.

The third insulating layer INS3 may be disposed on the first pixel electrode PE1. The third insulating layer INS3 may prevent an electrical short circuit between the first pixel electrode PE1 and the second pixel electrode PE2. The third insulating layer INS3 may include at least one of silicon oxide (SiOₓ), silicon nitride (SiNₓ), silicon oxynitride (SiOₓN_{y}), aluminum oxide (AlOₓ), and titanium oxide (TiOₓ).

The second pixel electrode PE2 may contact the second end portion EP2 of the first light emitting element LD1, and be disposed on the first insulating layer INS1, the second insulating layer INS2, and the third insulating layer INS3. The second pixel electrode PE2 may be a cathode electrode electrically connected to the second power line PL2.

As shown in FIG. 9, the first pixel electrode PE1 and the second pixel electrode PE2 may be disposed on different layers through different processes. However, this is merely illustrative, and the first pixel electrode PE1 and the second pixel electrode PE2 may be formed of a same material through a same process.

The first pixel electrode PE1 and the second pixel electrode PE2 may include a conductive material. For example, the first pixel electrode PE1 and the second pixel electrode PE2 may include a transparent conductive material including at least one of Indium Tin Oxide (ITO), Indium Zinc Oxide (IZO), and Indium Tin Zinc Oxide (ITZO). However, this is merely illustrative, and the embodiment of the disclosure is not limited to the above-described example.

The fourth insulating layer INS4 may be disposed on the third insulating layer INS3, and cover the first pixel electrode PE1 and the second pixel electrode PE2. The fourth insulating layer INS4 may protect lower components of the display element layer DPL. In an embodiment, the fourth insulating layer INS4 may be integral on the whole of the first emission area EMA1 and the first non-emission area NEA1. The fourth insulating layer INS4 may extend onto the bank BNK.

The fourth insulating layer INS4 may include at least one of silicon oxide (SiOₓ), silicon nitride (SiNₓ), silicon oxynitride (SiOₓN_{y}), aluminum oxide (AlOₓ), and titanium oxide (TiOₓ).

The first color conversion layer CCL1 may be disposed on the fourth insulating layer INS4 of the first emission area EMA1. The first color conversion layer CCL1 may change a wavelength of light provided from the first light emitting element LD1 or allow light provided from the first light emitting element LD1 to be transmitted therethrough. In an embodiment, the first light emitting element LD1 may emit light of the third color (e.g., light of blue).

For example, in case that the first sub-pixel SPXL1 is a pixel (e.g., a red pixel) emitting light of the first color (e.g., light of red), the first color conversion layer CCL1 may include a first color conversion particle QD1. The first color conversion particle QD1 may convert light of the third color (e.g., blue light) into light of the first color (e.g., red light). The first color conversion particle QD1 (e.g., a quantum dot) may absorb light of the third color (e.g., blue light) and emit light of the first color (e.g., red light) by shifting a wavelength of the blue light according to energy transition.

A dummy bank D_BNK (or dummy pattern) may be disposed on the bank BNK of the first non-emission area NEA1. In an embodiment, the dummy bank D_BNK may be disposed directly on the fourth insulating layer INS4 on the bank BNK in the first non-emission area NEA1. However, this is merely illustrative, and the dummy bank D_BNK may be disposed directly on the bank BNK in the first non-emission area NEA1 in which the fourth insulating layer INS4 is removed.

In an embodiment, the dummy bank D_BNK may include an inorganic insulating material. For example, the dummy bank D_BNK may include at least one of silicon oxide (SiOₓ), silicon nitride (SiNₓ), silicon oxynitride (SiOₓN_{y}), aluminum oxide (AlOₓ), and titanium oxide (TiOₓ).

In an embodiment, the dummy bank D_BNK may include a black material having a light blocking property and/or a reflective material. The dummy bank D_BNK may prevent a light leakage defect in which light (or beam) is leaked between the first sub-pixel SPXL1 and sub-pixels adjacent thereto. For example, the dummy bank D_BNK may be a black matrix. As another example, the dummy bank D_BNK may include a carbon black, but the disclosure is not limited thereto. Accordingly, the light emission efficiency of the first light emitting element LD1 and the first sub-pixel SPXL1 can be improved.

Also, the dummy bank D_BNK may be configured to include at least one light blocking material and/or at least one reflective material, to allow light emitted from the first light emitting element LD1 to further advance in an image display direction of the display device DD (e.g., the third direction DR3), thereby improving the light emission efficiency.

In an embodiment, the dummy bank D_BNK may include layers configured with (or formed as) a combination of the above-described materials or a material. For example, the dummy bank D_BNK may be formed of various materials through various processes so as to reduce a step difference with an area (portion) adjacent to the first color conversion layer CCL1.

The capping layer CPL may be disposed on the first color conversion layer CCL1 and the dummy bank D_BNK. In an embodiment, the capping layer CPL may be entirely (or wholly) provided in the display area DA, and be disposed directly on the dummy bank D_BNK and the first color conversion layer CCL1.

The capping layer CPL may be an inorganic layer (or inorganic insulating layer) including an inorganic material. For example, the capping layer CPL may include at least one of silicon oxide (SiOₓ), silicon nitride (SiNₓ), silicon oxynitride (SiOₓN_{y}), and metal oxide such as aluminum oxide (AlOₓ).

The capping layer CPL may cover the first color conversion layer CCL1, thereby protecting the first color conversion layer CCL1. For example, the capping layer CPL may prevent the first color conversion layer CCL1 from being damaged or contaminated due to infiltration of an impurity such as moisture or air from the outside.

In embodiments, the first sub-pixel SPXL1 may further include a planarization layer which is disposed on the capping layer CPL, reduces a step difference occurring due to components disposed on the bottom thereof, and provides a flat surface on the top thereof.

The color filter layer may be disposed on the capping layer CPL. For example, the color filter layer may include the first color filter CF1.

The color filter layer may allow light of a specific color to be selectively transmitted therethrough. For example, in case that the first sub-pixel SPXL1 includes the first color filter CF1, the first color filter CF1 may include a color filter material for allowing light of a specific color, which is converted in the first color conversion layer CCL1, to be selectively transmitted therethrough. In an example, the first color filter CF1 may allow light of the first color (e.g., red light) provided from the first color conversion layer CCL1 to be selectively transmitted therethrough.

The first color filter CF1 may overlap the first emission area EMA1 of the first sub-pixel SPXL1. For example, the first color filter CF1 may be disposed while overlapping the first emission area EMA1 of the first sub-pixel SPXL1 emitting light of the first color (e.g., red light).

In an embodiment, the first color filter CF1 may be stacked while overlapping at least a portion of the first non-emission area NEA1. Thus, a stack structure (e.g., the first color filter CF1) of the color filter layer in the first non-emission area NEA1 has a light blocking function, and can function to improve display quality.

The overcoat layer OC may be disposed on the color filter layer (or the first color filter CF1) and the capping layer CPL. The overcoat layer OC may be entirely (or wholly) provided throughout the first to third sub-pixels SPXL1 to SPXL3. The overcoat layer OC may cover a lower member. The overcoat layer OC may prevent moisture or air from infiltrating into the above-described lower member. Also, the overcoat layer OC may protect the above-described lower member from a foreign matter such as dust.

The overcoat layer OC may include an organic material such as acryl resin, epoxy resin, phenolic resin, polyamide resin, polyimide resin, unsaturated polyester resin, poly-phenylene ether resin, poly-phenylene sulfide resin, or benzocyclobutene (BCB). However, this is merely illustrative, and the embodiment of the disclosure is not limited thereto. For example, the overcoat layer OC may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

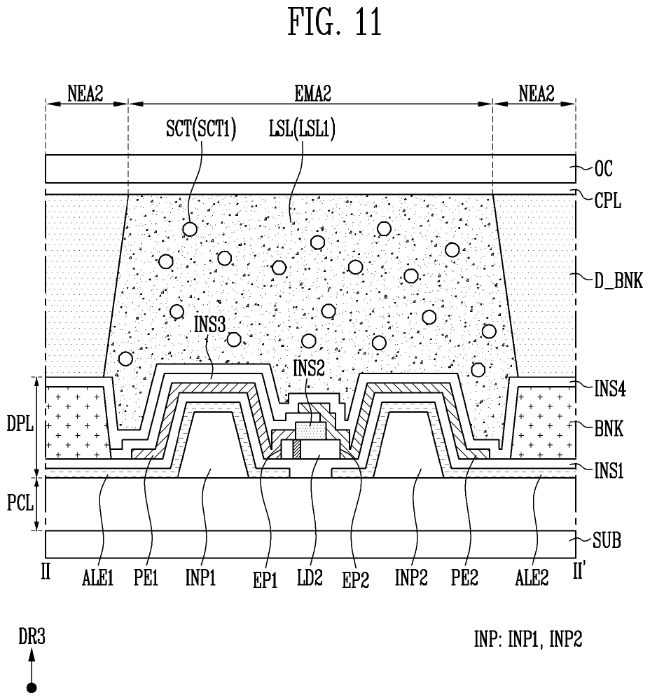

FIG. 11 is a schematic sectional view illustrating an example taken along line II-II′ shown in FIG. 7. FIG. 11 illustrates a sectional structure of the second sub-pixel SPXL2 described with reference to FIG. 7.

A sectional structure of a second sub-pixel shown in FIG. 11 (e.g., the second sub-pixel SPXL2 shown in FIG. 7) is distinguishable from the sectional structure of the first sub-pixel SPXL1 described with reference to FIG. 9, at least in that the second sub-pixel does not include any color conversion layer and any color filter layer but includes a light scattering layer LSL, and therefore, repetitive descriptions will not be provided. Portions not particularly described in FIG. 11 are substantially identical to the portions described with reference to FIG. 9. In FIG. 11, identical or similar reference numerals may represent components subsequently similar to the components described with reference to FIG. 9.

Referring to FIGS. 3, 4A, 6, 7, and 11, the second sub-pixel SPXL2 may include a substrate SUB, a pixel circuit layer PCL, a display element layer DPL, and a light scattering layer LSL (e.g., a first light scattering layer LSL1). In an embodiment, the second sub-pixel SPXL2 may further include a capping layer CPL and an overcoat layer OC, which are disposed on the display element layer DPL.

The display element layer DPL may include an insulating pattern INP (e.g., a first insulating pattern INP1 and a second insulating pattern INP2), a first alignment electrode ALE1, a second alignment electrode ALE2, a bank BNK, a second light emitting element LD2, a first pixel electrode PE1, a second pixel electrode PE2, a first insulating layer INS1, a second insulating layer INS2, a third insulating layer INS3, and a fourth insulating layer INS4.

The light scattering layer LSL may be disposed on the fourth insulating layer INS4 of the second emission area EMA2. The light scattering layer LSL may allow at least a portion of light provided from the second light emitting element LD2 to be scattered thereby or to be transmitted therethrough. In an embodiment, the second light emitting element LD2 may emit light of the second color (e.g., light of green).

For example, in case that the second sub-pixel SPXL2 is a pixel (e.g., a green pixel) emitting light of the second color (e.g., light of green), a light scattering particle SCT (e.g., a first light scattering particle SCT1) of the light scattering layer LSL included in the second sub-pixel SPXL2 may allow light of the second color (e.g., green light) provided from the second light emitting element LD2 to be scattered thereby and to be transmitted therethrough without color conversion. In an example, the light scattering particle SCT (e.g., a scattering particle) may emit light of the second color (e.g., green light) by allowing light to be scattered in a random direction thereby regardless of the incident direction of incident light while not substantially converting a peak wavelength of the incident light, e.g., light of the second color (e.g., green light).

The capping layer CPL may be disposed on the light scattering layer LSL and a dummy bank D_BNK. In an embodiment, as described with reference to FIG. 9, the capping layer CPL may be entirely (or wholly) provided in the display area DA.

The overcoat layer OC may be disposed on the capping layer CPL. In an embodiment, as described with reference to FIG. 9, the overcoat layer OC may be entirely (or wholly) provided through the first to third sub-pixels SPXL1 to SPXL3.

A third sub-pixel (e.g., the third sub-pixel SPXL3 shown in FIG. 8) may have a sectional structure substantially similar to the sectional structure of the second sub-pixel SPXL2 described with reference to FIGS. 7 and 11. For example, the sectional structure of the third sub-pixel (e.g., the third sub-pixel SPXL3 shown in FIG. 8) may be distinguishable from the sectional structure of the second sub-pixel SPXL2 described with reference to FIGS. 7 and 11, at least in that the third sub-pixel (e.g., the third sub-pixel SPXL3 shown in FIG. 8) includes a first light emitting element LD1 identical to the first light emitting element LD1 included in the first sub-pixel (e.g., the first sub-pixel SPXL1 shown in FIG. 6).

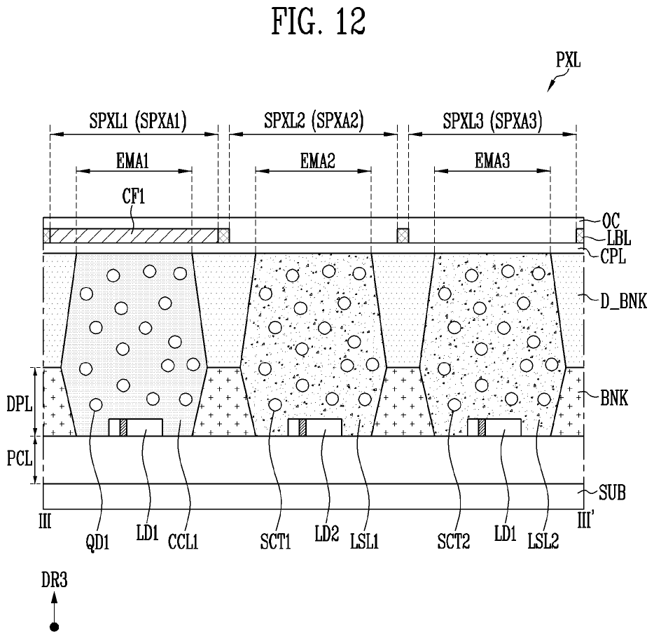

FIG. 12 is a schematic sectional view illustrating an example taken along line III-III′ shown in FIG. 5. FIG. 12 illustrates a sectional structure of a pixel PXL including the sub-pixels SPXL1 to SPXL3 described with reference to FIG. 5.

The sectional structure of the sub-pixels SPXL1 to SPXL3 included in the pixel PXL shown in FIG. 12 is substantially identical or similar to the sectional structure of the sub-pixels SPXL1 to SPXL3 described with reference to FIG. 11, and therefore, repetitive descriptions will not be provided. Portions not particularly described in FIG. 12 follow those of the above-described embodiment. In addition, identical reference numerals refer to identical components, and similar reference numerals refer to similar components.

Referring to FIGS. 3, 5, 9, 10, 11, and 12, the pixel PXL may include a first sub-pixel SPXL1, a second sub-pixel SPXL2, and a third sub-pixel SPXL3.

A bank BNK may be disposed between the sub-pixels SPXL1 to SPXL3 or at a boundary between the sub-pixels SPXL1 to SPXL3. The bank BNK may include openings respectively overlapping sub-pixel areas SPXA1 to SPXA3 of the sub-pixels SPXL1 to SPXL3. The openings may correspond to emission areas EMA1 to EMA3 of the sub-pixels SPXL1 to SPXL3, respectively. For example, the emission areas EMA1 to EMA3 of the sub-pixels SPXL1 to SPXL3 may be defined by the openings of the bank BNK, respectively.

A dummy bank D_BNK may be disposed on the bank BNK. Openings of the dummy bank D_BNK along with the openings of the bank BNK may define the emission areas EMA1 to EMA3 of the sub-pixels SPXL1 to SPXL3, respectively.

In an embodiment, at least some of the sub-pixels SPXL1 to SPXL3 may include a light emitting element emitting light of a same color.

For example, the first sub-pixel SPXL emitting light of the first color (e.g., red light) and the third sub-pixel SPXL3 emitting light of the third color (e.g., blue light) may include a light emitting element emitting light of a same color. For example, the first sub-pixel SPXL1 and the third sub-pixel SPXL3 may include a first light emitting element LD1 emitting light of the third color (e.g., blue light). The second sub-pixel SPXL2 emitting light of the second color (e.g., green light) may include a light emitting element emitting light of a color different from the color of light emitted from the first sub-pixel SPXL1 and the third sub-pixel SPXL3. For example, the second sub-pixel SPXL2 may include a second light emitting element LD2 emitting light of the second color (e.g., green light).

In an embodiment, the first sub-pixel SPXL1 may include a first color conversion layer CCL1 and a first color filter CF1. As described with reference to FIGS. 5, 6, and 9, light of the third color (e.g., blue light) emitted from the first light emitting element LD1 included in the first sub-pixel SPXL1 may be provided to the first color conversion layer CCL1, and first color conversion particles QD1 of the first color conversion layer CCL1 may emit light of the first color (e.g., red light) by shifting a wavelength of light of the third color (e.g., blue light), which is emitted from the first light emitting element LD1. The first color filter CF1 may allow the light of the first color (e.g., red light), which is provided from the first color conversion layer CCL1, to be selectively transmitted therethrough. Accordingly, the first sub-pixel SPXL1 may emit light of the first color (e.g., red light).

In an embodiment, in a manufacturing process of the pixel PXL, the first sub-pixel SPXL1 may be manufactured not by using a red light emitting element having relatively low light efficiency but by using a blue light emitting element (e.g., the first light emitting element LD1) having relatively high light efficiency, so that the luminance of the first sub-pixel SPXL1 can be improved. Blue light (light of the third color) having a relatively short wavelength in a visible light band may be incident into the first color conversion particles QD1 of the first color conversion layer CCL1, so that an absorption coefficient of the first color conversion particles QD1 can be increased. Accordingly, the efficiency of light finally emitted from the first sub-pixel SPXL1 can be improved, and excellent color reproducibility can be ensured. In the manufacturing process of the pixel PXL, the first sub-pixel SPXL1 and the third sub-pixel SPXL3 may be manufactured by using the first light emitting element LD1 (e.g., the blue light emitting element) emitting light of a same color, so that a manufacturing process of the display device DD can be simplified.

The dummy bank D_BNK may provide a space in which the first color conversion layer CCL1 can be provided. For example, a desired kind and/or a desired amount of first color conversion layer CCL1 may be supplied (or provided) in a spaced partitioned by an opening of the dummy bank D_BNK. For example, in the manufacturing process of the pixel PXL, after the dummy bank D_BNK is provided, the first color conversion layer CCL1 may be supplied (or provided) in a space partitioned by an opening of the dummy bank D_BNK, which corresponds to a first sub-pixel area SPXA1.

In an embodiment, the second sub-pixel SPXL2 and the third sub-pixel SPXL3 may include a light scattering layer. For example, the second sub-pixel SPXL2 may include a first light scattering layer LSL1, and the third sub-pixel SPXL3 may include a second light scattering layer LSL2. As described with reference to FIGS. 5, 7, 8, and 11, light of the second color (e.g., green light) emitted from the second light emitting element LD2 included in the second sub-pixel SPXL2 may be provided to the first light scattering layer LSL1, and allow the light of the second color (e.g., the green light), which is provided to the first light scattering layer LSL1, to be scattered thereby and to be transmitted therethrough without color conversion. Accordingly, the second sub-pixel SPXL2 may emit light of the second color (e.g., green light). Light of the third color (e.g., blue light) emitted from the first light emitting element LD1 included in the third sub-pixel SPXL3 may be provided to the second light scattering layer LSL2, and allow the light of the third color (e.g., the blue light), which is provided to the second light scattering layer LSL2, to be scattered thereby and to be transmitted therethrough without color conversion. Accordingly, the third sub-pixel SPXL3 may emit light of the third color (e.g., blue light).

In an embodiment, the light scattering layer (e.g., the first light scattering layer LSL1 and the second light scattering layer LSL2) may be formed by coating a light scattering material (or light scattering particle) on the entire display area DA and performing a process of etching and curing the light scattering material. For example, the light scattering material (or light scattering particle) may be patterned such that the first light scattering layer LSL1 is formed in only a second emission area EMA2 of the second sub-pixel SPXL2 and the second light scattering layer LSL2 is formed in only a third emission area EMA3 of the third sub-pixel SPXL3.

In an embodiment, in case that a light scattering particle (e.g., a first light scattering particle SCT1 and a second light scattering particle SCT2) is omitted, the light scattering layer (e.g., the first light scattering layer LSL1 and the second light scattering layer LSL2) configured with (or formed as) transparent polymer may be provided to a second sub-pixel area SPXA2 and a third sub-pixel area SPXA3.

In an embodiment, since the second sub-pixel SPXL2 and the third sub-pixel SPXL3 do not include any color conversion layer and any color filter layer, color conversion caused by a color conversion layer and deterioration of light efficiency according to color absorption caused by a color filter layer may be reduced, so that luminances of the second sub-pixel SPXL2 and the third sub-pixel SPXL3 can be improved.

In the manufacturing process of the pixel PXL, in case that the second sub-pixel SPXL2 and the third sub-pixel SPXL3 are manufactured by using a color conversion layer and a color filter layer, the color conversion layer including a color conversion particle may be required to be provided to each of the second sub-pixel area SPXA2 and the third sub-pixel area SPXA3 through a separate process (e.g., an inkjet printing process), and the color filter layer may be required to be provided to each of the second sub-pixel area SPXA2 and the third sub-pixel area SPXA3 through an additional process (e.g., a process using a mask). On the other hand, in a manufacturing process of the pixel PXL in accordance with embodiments of the disclosure, the light scattering layer (e.g., the first light scattering layer LSL1 and the second light scattering layer LSL2) including the light scattering particle may be provided to the second sub-pixel area SPXA2 and the third sub-pixel area SPXA3 through a process, and a separate process for depositing the color filter layer may be omitted. Accordingly, the manufacturing process of the display device DD can be simplified.

A capping layer CPL may be disposed on the first color conversion layer CCL1, the first light scattering layer LSL1, the second light scattering layer LSL2, and the dummy bank D_BNK. In an embodiment, the capping layer CPL may be entirely (or wholly) provided in the display area DA. For example, the capping layer CPL may be entirely (or wholly) provided on a pixel area of the pixel PXL. For example, the sub-pixels SPXL1 to SPXL3 may share the capping layer CPL.

A light blocking layer LBL (or light blocking pattern) may be selectively further disposed on the capping layer CPL. The light blocking layer LBL may include a light blocking material for preventing a light leakage defect in which light (or beam) is leaked between adjacent sub-pixels among the sub-pixels SPXL1 to SPXL3. Accordingly, the light blocking layer LBL can prevent color mixture of rays of light respectively emitted from the adjacent sub-pixels SPXL1 to SPXL3.

As described with reference to FIG. 5, the sub-pixel areas SPXA1 to SPXA3 may be defined by the light blocking layer LBL. For example, the sub-pixel areas SPXA1 to SPXA3 may be defined as areas in which the light blocking layer LBL is not disposed. In an example, the sub-pixel areas SPXA1 to SPXA3 may be defined by openings of the light blocking layer LBL.

An overcoat layer OC may be disposed on the capping layer CPL. The overcoat layer OC may be entirely (or wholly) provided in the sub-pixels SPXL1 to SPXL3.

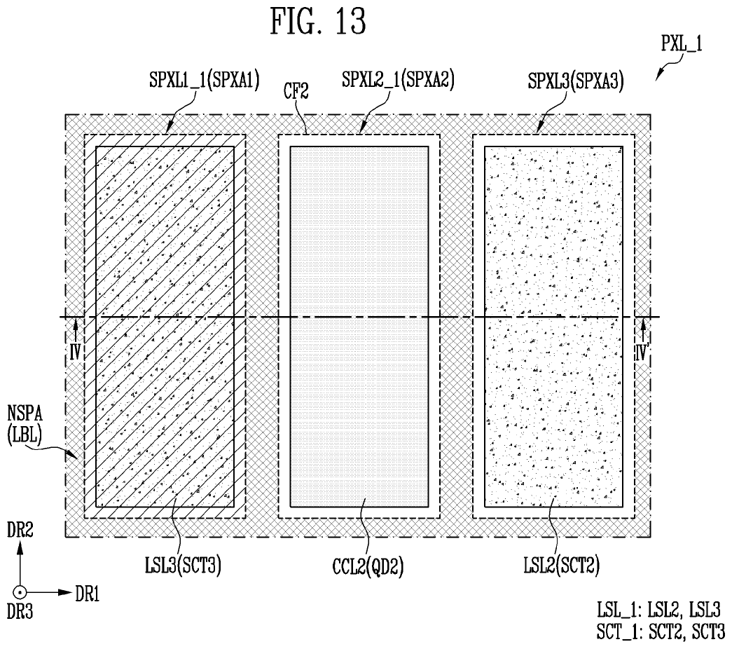

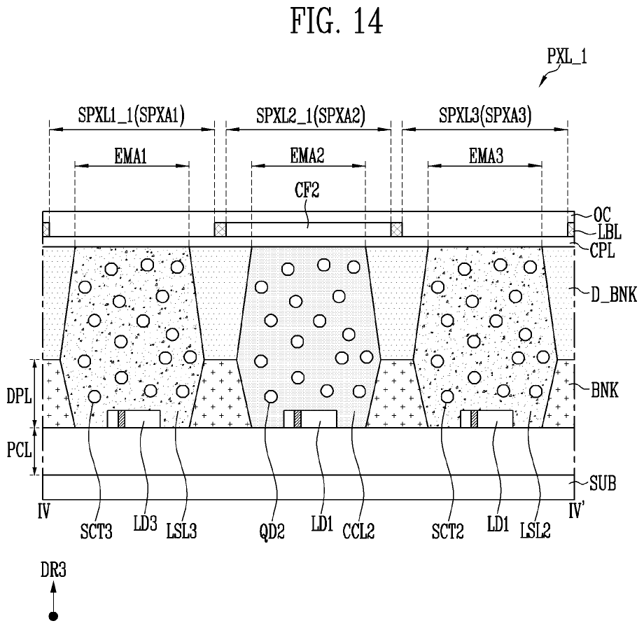

FIG. 13 is a schematic plan view illustrating an example of the pixel included in the display device shown in FIG. 3. FIG. 14 is a schematic sectional view illustrating an example taken along line IV-IV′ shown in FIG. 13. FIGS. 13 and 14 illustrate a modified embodiment of FIGS. 5 and 12 in relation to structures of a first sub-pixel SPXL1_1 and a second sub-pixel SPXL2_1.

In FIGS. 13 and 14, portions different from those of the above-described embodiment will be mainly described to avoid redundancy. Also, portions not particularly described in FIGS. 13 and 14 follow those of the above-described embodiment. In addition, identical reference numerals refer to identical components, and similar reference numerals refer to similar components.

FIG. 13 illustrates a structure for defining sub-pixel areas SPXA1, SPXA2, and SPXA3 of sub-pixels SPXL1_1, SPXL2_1, and SPXL3 included in a pixel PXL_1.

Although FIG. 3 illustrates an embodiment of a structure in which the sub-pixels SPXL1_1, SPXL2_1, and SPXL3 are arranged in the first direction DR1, this is merely illustrative, and the embodiment of the disclosure is not limited thereto.

Referring to FIGS. 3 and 13, the pixel PXL_1 may include sub-pixels SPXL1_1, SPXL2_1, and SPXL3 each emitting light of a color (e.g., a predetermined or selectable color). For example, the pixel PXL_1 may include a first sub-pixel SPXL1_1 emitting light of the first color (e.g., red), a second sub-pixel SPXL2_1 emitting light of the second color (e.g., green), and a third sub-pixel SPXL3 emitting light of the third color (e.g., blue).

In an embodiment, as described with reference to FIG. 3, the second sub-pixel SPXL2_1 and the third sub-pixel SPXL3 among the sub-pixels SPXL1_1, SPXL2_1, and SPXL3 may include a light emitting element (e.g., a first light emitting element) emitting light of the third color (e.g., light of blue). The second sub-pixel SPXL2_1 may include a color conversion layer (e.g., a second color conversion layer CCL2) and a color filter layer (e.g., a second color filter CF2), which are disposed above the light emitting element (e.g., the first light emitting element), to emit light of the second color (e.g., light of green). The first sub-pixel SPXL1_1 may include a light emitting element (e.g., a third light emitting element) emitting light of the first color (e.g., light of red).

In an embodiment, the second sub-pixel SPXL2_1 may include the second color conversion layer CCL2 and the second color filter CF2. Light (e.g., light of the third color) emitted from the first light emitting element included in the second sub-pixel SPXL2_1 may be provided to the second color conversion layer CCL2, and second color conversion particles QD2 of the second color conversion layer CCL2 may convert light of the third color (e.g., blue), which is emitted from the first light emitting element, into light of the second color (e.g., green). The color-converted light may be provided to the second color filter CF2, and the second sub-pixel SPXL2_1 may emit light of the second color (e.g., green), based on the light provided to the second color filter CF2 to be transmitted therethrough.

The second color filter CF2 may be disposed (or provided) corresponding to a second sub-pixel area SPXA2 of the second sub-pixel SPXL2_1. The second color filter CF2 may allow light advancing toward the second color filter CF2 to be selectively transmitted therethrough. For example, the second color filter CF2 is a second color filter (e.g., a green color filter), and may allow light of the second color (e.g., green) to be selectively transmitted therethrough.

In an embodiment, each of the first sub-pixel SPXL1_1 and the third sub-pixel SPXL3 may include a light scattering layer LSL_1 including a light scattering particle SCT_1. For example, the first sub-pixel SPXL1_1 may include a third light scattering layer LSL3 including a third light scattering particle SCT3, and the third sub-pixel SPXL3 may include a second light scattering layer LSL2 including a second light scattering particle SCT2.

In order to describe in more detail a sectional structure of the pixel PXL_1, further referring to FIG. 14, the pixel PXL_1 may include the first sub-pixel SPXL1_1, the second sub-pixel SPXL2_1, and the third sub-pixel SPXL3.

In an embodiment, at least some of the sub-pixels SPXL1_1, SPXL2_1, and SPXL3 may include a light emitting element emitting light of a same color.

For example, the second sub-pixel SPXL2_1 emitting light of the second color (e.g., green light) and the third sub-pixel SPXL3 emitting light of the third color (e.g., blue light) may include a light emitting element emitting light of a same color. For example, the second sub-pixel SPXL2_1 and the third sub-pixel SPXL3 may include a first light emitting element LD1 emitting light of the third color (e.g., blue light). The first sub-pixel SPXL1_1 emitting light of the first color (e.g., red light) may include a light emitting element emitting light of a color different from the color of light emitted from the second sub-pixel SPXL2_1 and the third sub-pixel SPXL3. For example, the first sub-pixel SPXL1_1 may include a third light emitting element LD3 emitting light of the first color (e.g., red light).

In an embodiment, the second sub-pixel SPXL2_1 may include a second color conversion layer CCL2 and a second color filter CF2. As described above, light of the third color (e.g., blue light), which is emitted from the first light emitting element LD1 included in the second sub-pixel SPXL2_1, may be provided to the second color conversion layer CCL2, and second color conversion particles QD2 of the second color conversion layer CCL2 may emit light of the second color (e.g., green light) by shifting a wavelength of the light of the third color (e.g., the blue light), which is emitted from the first light emitting element LD1. The second color filter CF2 may allow the light of the second color (e.g., the green light), which is provided from the second color conversion layer CCL2, to be selectively transmitted therethrough. Accordingly, the second sub-pixel SPXL2_1 may emit light of the second color (e.g., green light).

In embodiments, in a manufacturing process of the pixel PXL_1, the second sub-pixel SPXL2_1 may be manufactured by using a blue light emitting element (e.g., the first light emitting element LD1) having relatively high light efficiency, so that the luminance of the second sub-pixel SPXL2_1 can be improved. In particular, since the luminance of the display device DD is greatly influenced by light efficiency of the second sub-pixel SPXL2_1 emitting green light (light of the second color), the second sub-pixel SPXL2_1 may be manufactured by using a blue light emitting element having relatively high light efficiency, so that the luminance of the display device DD can be improved.

Blue light (light of the third color) having a relatively short wavelength in a visible light band may be incident into the second color conversion particles QD2 of the second color conversion layer CCL2, so that an absorption coefficient of the second color conversion particles QD2 can be increased. Accordingly, the efficiency of light finally emitted from the second sub-pixel SPXL2_1 can be improved, and excellent color reproducibility can be ensured.

In the manufacturing process of the pixel PXL_1, the second sub-pixel SPXL2_1 and the third sub-pixel SPXL3 may be manufactured by using the first light emitting element LD1 (e.g., the blue light emitting element) emitting light of a same color, so that a manufacturing process of the display device DD can be simplified.

The dummy bank D_BNK may provide a space in which the second color conversion layer CCL2 can be provided. For example, a desired kind and/or a desired amount of second color conversion layer CCL2 may be supplied (or provided) in a spaced partitioned by an opening of the dummy bank D_BNK. For example, in the manufacturing process of the pixel PXL_1, after the dummy bank D_BNK is provided, the second color conversion layer CCL2 may be supplied (or provided) in a space partitioned by an opening of the dummy bank D_BNK, which corresponds to a second sub-pixel area SPXA2.

In an embodiment, the first sub-pixel SPXL1_1 and the third sub-pixel SPXL3 may include a light scattering layer. For example, the first sub-pixel SPXL1_1 may include a third light scattering layer LSL3, and the third sub-pixel SPXL3 may include a second light scattering layer LSL2. As described above, light of the first color (e.g., red light) emitted from the third light emitting element LD3 included in the first sub-pixel SPXL1_1 may be provided to the third light scattering layer LSL3, and allow the light of the first color (e.g., the red light), which is provided to the third light scattering layer LSL3, to be scattered thereby and to be transmitted therethrough without color conversion. Accordingly, the first sub-pixel SPXL1_1 may emit light of the first color (e.g., red light). Light of the third color (e.g., blue light) emitted from the first light emitting element LD1 included in the third sub-pixel SPXL3 may be provided to the second light scattering layer LSL2, and allow the light of the third color (e.g., the blue light), which is provided to the second light scattering layer LSL2, to be scattered thereby and to be transmitted therethrough without color conversion. Accordingly, the third sub-pixel SPXL3 may emit light of the third color (e.g., blue light).

In an embodiment, the light scattering layer (e.g., the second light scattering layer LSL2 and the third light scattering layer LSL3) may be formed by coating a light scattering material (or light scattering particle) on the entire display area DA and performing a process of etching and curing the light scattering material. For example, the light scattering material (or light scattering particle) may be patterned such that the third light scattering layer LSL3 is formed in only a first emission area EMA1 of the first sub-pixel SPXL1_1 and the second light scattering layer LSL2 is formed in only a third emission area EMA3 of the third sub-pixel SPXL3.

In an embodiment, in case that a light scattering particle (e.g., a second light scattering particle SCT2 and a third light scattering particle SCT3) is omitted, the light scattering layer (e.g., the second light scattering layer LSL2 and the third light scattering layer LSL3) configured with (or formed as) transparent polymer may be provided to a first sub-pixel area SPXA1 and a third sub-pixel area SPXA3.

In an embodiment, since the third sub-pixel SPXL3 does not include any color conversion layer and any color filter layer, color conversion caused by a color conversion layer and deterioration of light efficiency according to color absorption caused by a color filter layer may be reduced, so that the luminance of the third sub-pixel SPXL3 can be improved.

In the manufacturing process of the pixel PXL_1, in case that the first sub-pixel SPXL1_1 and the third sub-pixel SPXL3 are manufactured by using a color conversion layer and a color filter layer, the color conversion layer including a color conversion particle may be required to be provided to each of the first sub-pixel area SPXA1 and the third sub-pixel area SPXA3 through a separate process (e.g., an inkjet printing process), and the color filter layer may be required to be provided to each of the first sub-pixel area SPXA1 and the third sub-pixel area SPXA3 through an additional process (e.g., a process using a mask). On the other hand, in a manufacturing process of the pixel PXL_1 in accordance with embodiments of the disclosure, the light scattering layer (e.g., the second light scattering layer LSL2 and the third light scattering layer LSL3) including the light scattering particle may be provided to the first sub-pixel area SPXA1 and the third sub-pixel area SPXA3 through a process, and a separate process for depositing the color filter layer may be omitted. Accordingly, the manufacturing process of the display device DD can be simplified.

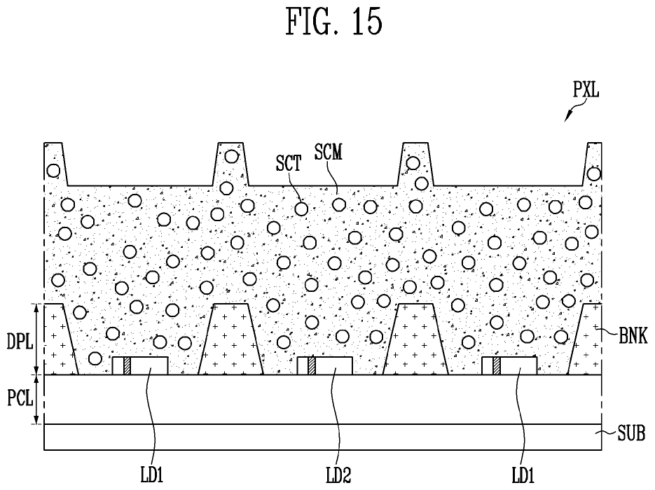

FIGS. 15 to 21 are schematic sectional views illustrating a manufacturing method for the display device in accordance with embodiments of the disclosure.

In FIGS. 15 to 21, a manufacturing method for the display device including the pixel PXL described with reference to FIGS. 5 to 12 will be described.

Referring to FIGS. 5 to 12 and 15 to 21, the manufacturing method may include forming a display element layer DPL including a bank BNK and light emitting elements LD1 and LD2, forming a light scattering layer LSL on the display element layer DPL1, forming a dummy bank D_BNK on the bank BNK, forming a color conversion layer (e.g., a first color conversion layer CCL1) on the display element layer DPL, forming a capping layer CPL and a light blocking layer LBL on the light scattering layer LSL and the color conversion layer, forming a color filter layer (e.g., a first color filter CF1) on the capping layer CPL, and forming an overcoat layer OC.

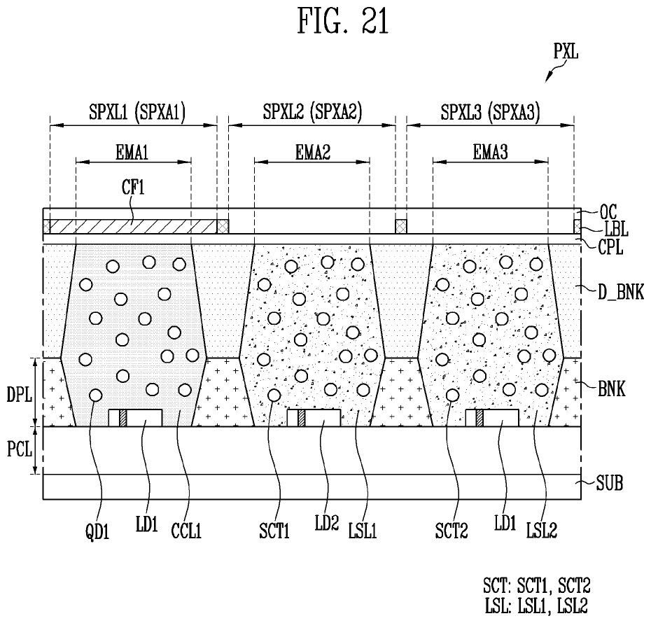

For convenience of description, FIGS. 15 and 21 illustrate configurations of a pixel circuit layer PCL and a display element layer DPL. For example, the display element layer DPL may include light emitting elements LD1 and LD2 and a bank BNK, and the bank BNK may define (or partition) emission areas EMA1, EMA2, and EMA3 included in a pixel PXL.

First, as shown in FIG. 15, a light scattering material SCM may be coated on the display element layer DPL of the pixel PXL. The light scattering material SCM may be formed on the display element layer DPL through various coating processes. For example, the light scattering material SCM may be coated on the display element layer DPL through an inkjet printing process.

The light scattering material SCM may include a light scattering particle SCT for allowing at least a portion of light to be scattered thereby.

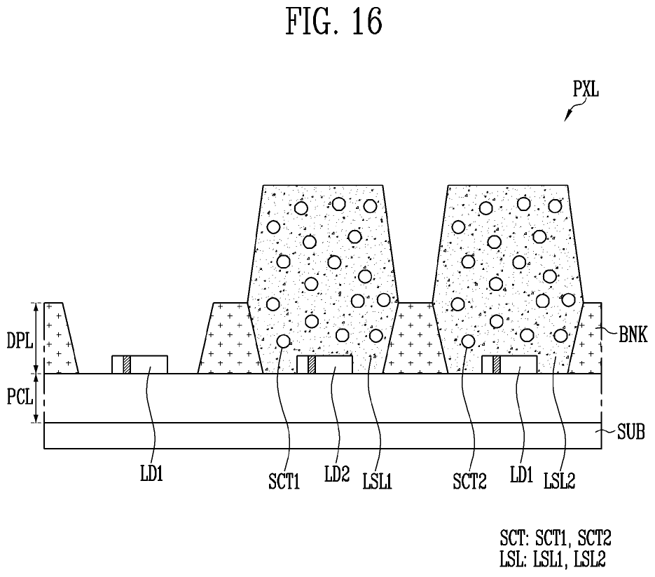

Subsequently, as shown in FIG. 16, the light scattering material SCM at a portion except areas corresponding to a second emission area EMA2 of a second sub-pixel SPXL2 and a third emission area EMA3 of a third sub-pixel SPXL3 may be removed through a mask, and a light scattering layer LSL may be formed by thermally curing the light scattering material SCM remaining in the second emission area EMA2 and the third emission area EMA3. For example, a first light scattering layer LSL1 corresponding to the second sub-pixel SPXL2 and a second light scattering layer LSL2 corresponding to the third sub-pixel SPXL3 may be formed.

As described with reference to FIGS. 15 and 16, in the manufacturing method in accordance with the embodiments of the disclosure, the first light scattering layer LSL1 and the second light scattering layer LSL2, which are included in the second sub-pixel SPXL2 and the third sub-pixel SPXL3, are formed through a same process (a process), and thus a manufacturing process of the display device can be simplified.

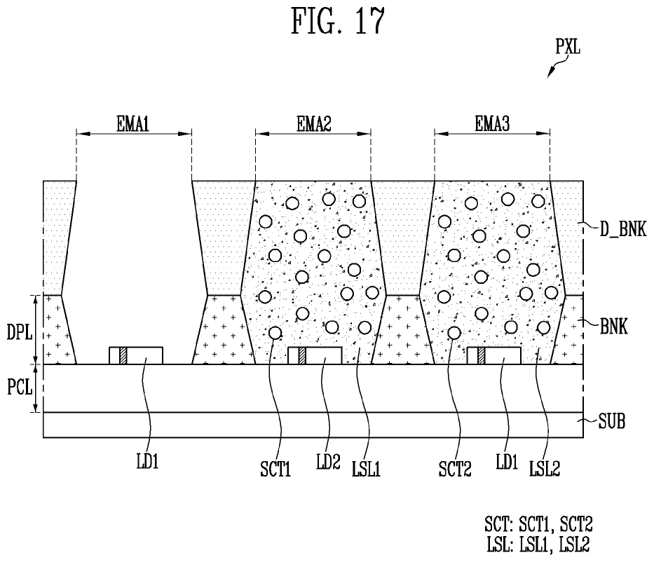

Subsequently, as shown in FIG. 17, a dummy bank D_BNK may be formed on the bank BNK. For example, the dummy bank D_BNK may be formed in non-emission areas (e.g., the non-emission areas NEA1, NEA2, and NEA3 described with reference to FIGS. 6 to 11) except the emission areas EMA1, EMA2, and EMA3.

For example, the dummy bank D_BNK including an inorganic material may be formed through a chemical vapor deposition process, or the like. In another example, the dummy bank D_BNK including an organic material may be formed through patterning using a mask and exposure after an organic material is coated.

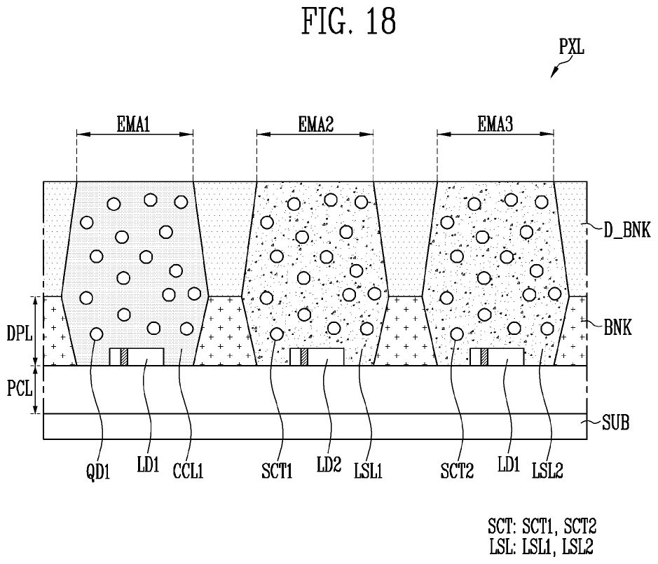

Subsequently, as shown in FIG. 18, a first color conversion layer CCL1 may be formed by coating a color conversion material in a first emission area EMA1 of a first sub-pixel SPXL1 through a coating process (e.g., an inkjet printing process), and thermally curing the color conversion material coated in the first emission area EMA1.

The first color conversion layer CCL1 may include first color conversion particles QD1 for converting light of a third color (e.g., blue light), which is emitted from a light emitting element (e.g., a first light emitting element LD1), into light of a first color (e.g., red light).

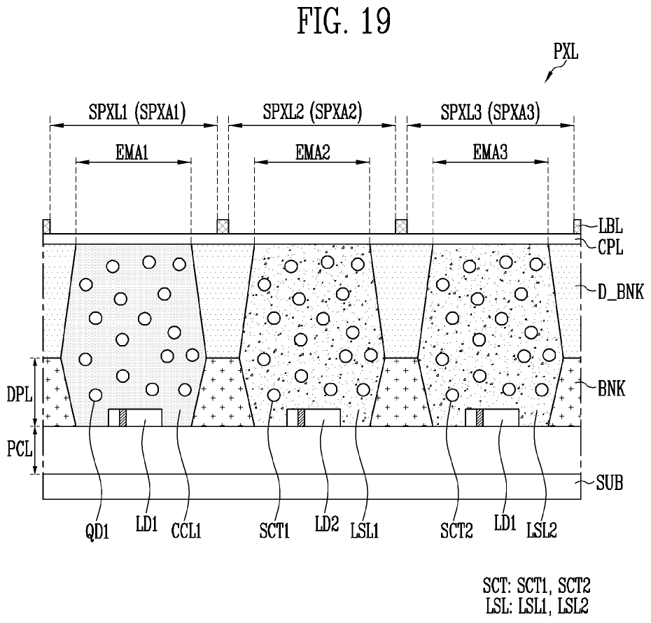

Subsequently, as shown in FIG. 19, a capping layer CPL may be formed on the first color conversion layer CCL1, the light scattering layer LSL, and the dummy bank D_BNK. For example, the capping layer CPL may be entirely (or wholly) formed in a display area DA through a chemical vapor deposition process, or the like.

A light blocking layer LBL may be formed on the capping layer CPL. For example, the light blocking layer LBL may be formed in an area not overlapping the emission areas EMA1, EMA2, and EMA3. The light blocking layer LBL may be provided in an area except sub-pixel areas SPXA1 to SPXA3, and accordingly, the sub-pixel areas SPXA1 to SPXA3 may be defined by the light blocking layer LBL.

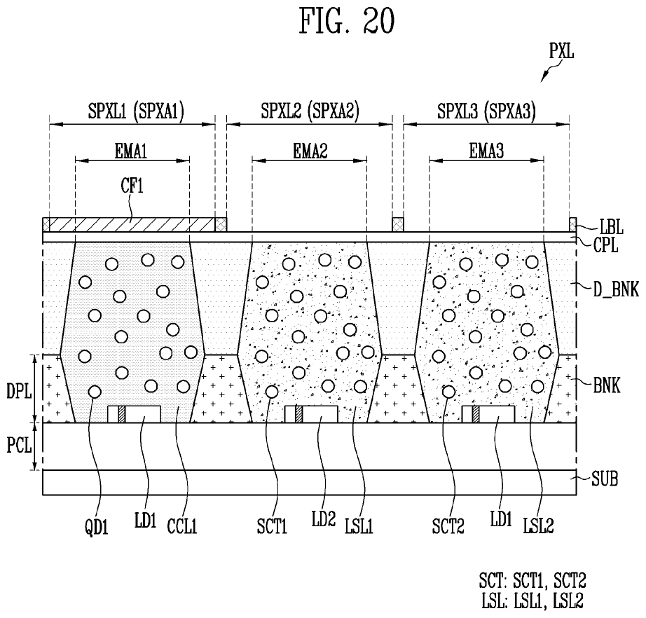

Subsequently, as shown in FIG. 20, a color filter layer (e.g., a first color filter CF1) may be formed corresponding to a first sub-pixel area SPXA1 of the first sub-pixel SPXL1. The first color filter CF1 may overlap the first color conversion layer CCL1 of the first sub-pixel area SPXA1, and may not overlap the light blocking layer LBL. However, this is merely illustrative, and the embodiment of the disclosure is not limited thereto. The first color filter CF1 may be provided to overlap at least a portion of the light blocking layer LBL.

Subsequently, as shown in FIG. 21, an overcoat layer OC may be formed on the capping layer CPL. For example, the overcoat layer OC may be entirely (or wholly) formed in the display area DA through a chemical vapor deposition process, or the like.

In the display device in accordance with the disclosure, at least some of sub-pixels included in the display device may include a light scattering layer, and have a structure in which a color conversion layer and/or a color filter layer are/is omitted. Accordingly, color conversion caused by the color conversion layer and deterioration of light efficiency according to color absorption caused by the color filter layer can be reduced (or eliminated), so that the light efficiency and luminance of the display device can be improved.

In the manufacturing method for the display device in accordance with the disclosure, a light scattering layer may be formed in a second sub-pixel area and a third sub-pixel area (or the first sub-pixel area and the third sub-pixel area) through a process, and a separate process for depositing a color filter layer in the second sub-pixel area and the third sub-pixel area (or the first sub-pixel area and the third sub-pixel area) may be omitted. Accordingly, a manufacturing process of the display device can be simplified.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display area and a non-display area; and
a pixel disposed on a substrate in the display area, wherein
the pixel includes:
a first sub-pixel disposed in a first sub-pixel area, the first sub-pixel emitting light of a first color;
a second sub-pixel disposed in a second sub-pixel area, the second sub-pixel emitting light of a second color; and
a third sub-pixel disposed in a third sub-pixel area, the third sub-pixel emitting light of a third color, and
each of two sub-pixels among the first sub-pixel, the second sub-pixel, and the third sub-pixel includes a light emitting element emitting light of the third color, and
the other sub-pixel among the first sub-pixel, the second sub-pixel, and the third sub-pixel includes a light emitting element emitting light of a color different from the third color.

2. The display device of claim 1, wherein
each of the first sub-pixel and the third sub-pixel includes a first light emitting element emitting light of the third color, and
the second sub-pixel includes a second light emitting element emitting light of the second color.

3. The display device of claim 2, wherein
the first sub-pixel includes a first color conversion layer including at least one first color conversion particle, and
each of the second sub-pixel and the third sub-pixel includes a light scattering layer including at least one light scattering particle.

4. The display device of claim 2, wherein the first sub-pixel includes:
a pixel circuit layer disposed on the substrate, the pixel circuit layer including a transistor;
a display element layer disposed on the pixel circuit layer, the display element layer including the first light emitting element disposed in a first emission area;
a first color conversion layer disposed on the display element layer to overlap the first emission area in a plan view, the first color conversion layer including at least one first color conversion particle; and
a color filter layer disposed on the first color conversion layer.

5. The display device of claim 4, wherein the display element layer further includes a bank provided in a first non-emission area, the bank including an opening corresponding to the first emission area.

6. The display device of claim 5, wherein the first sub-pixel further includes a dummy bank disposed on the bank, corresponding to the first non-emission area.

7. The display device of claim 6, wherein the first sub-pixel further includes a capping layer disposed between the first color conversion layer and the color filter.

8. The display device of claim 7, wherein the capping layer is disposed directly on the first color conversion layer and the dummy bank.

9. The display device of claim 2, wherein the second sub-pixel includes:
a pixel circuit layer disposed on the substrate, the pixel circuit layer including a transistor;
a display element layer disposed on the pixel circuit layer, the display element layer including the second light emitting element disposed in a second emission area; and
a first light scattering layer disposed on the display element layer to overlap the second emission area in a plan view, the first light scattering layer including at least one first light scattering particle.

10. The display device of claim 9, wherein the display element layer further includes a bank provided in a second non-emission area, the bank including an opening corresponding to the second emission area.

11. The display device of claim 10, wherein the second sub-pixel further includes a dummy bank disposed on the bank, corresponding to the second non-emission area.

12. The display device of claim 11, wherein the second sub-pixel further includes a capping layer disposed on the dummy bank and the first light scattering layer.

13. The display device of claim 2, wherein the third sub-pixel includes:
a pixel circuit layer disposed on the substrate, the pixel circuit layer including a transistor;
a display element layer disposed on the pixel circuit layer, the display element layer including the first light emitting element disposed in a third emission area; and
a second light scattering layer disposed on the display element layer to overlap the third emission area in a plan view, the second light scattering layer including at least one second light scattering particle.

14. The display device of claim 1, wherein
each of the second sub-pixel and the third sub-pixel includes a first light emitting element emitting light of the third color, and
the first sub-pixel includes a third light emitting element emitting light of the first color.

15. The display device of claim 14, wherein
the second sub-pixel includes a second color conversion layer including at least one second color conversion particle, and
each of the first sub-pixel and the third sub-pixel includes a light scattering layer including at least one light scattering particle.

16. The display device of claim 1, wherein
light of the first color is red light,
light of the second color is green light, and
light of the third color is blue light.

17. A manufacturing method for a display device, the method comprising:
forming a display element layer including light emitting elements and a bank;
forming a light scattering layer in each of a second sub-pixel area and a third sub-pixel area;
forming a dummy bank on the bank;
forming a color conversion layer in a first sub-pixel area; and
forming a color filter layer on the color conversion layer of the first sub-pixel area wherein the display device includes:
a first sub-pixel which is disposed in the first sub-pixel area and emits light of a first color;
a second sub-pixel which is disposed in the second sub-pixel area and emits light of a second color; and
a third sub-pixel which is disposed in the third sub-pixel area and emits light of a third color.

18. The method of claim 17, wherein the forming of the display element layer includes:
providing a first light emitting element emitting light of the third color in each of the first sub-pixel area and the third sub-pixel area; and
providing a second light emitting element emitting light of the second color in the second sub-pixel area.

19. The method of claim 17, wherein
the light of the first color is red light,
the light of the second color is green light, and
the light of the third color is blue light.

20. The method of claim 17, wherein
the light of the first color is green light,
the light of the second color is red light, and
the light of the third color is blue light.
